(19) United States
(12) Patent Application Publication
(10) Pub. No.: US 2025/0323118 A1
(43) Pub. Date: Oct. 16, 2025

(54) THERMAL VIAS FOR SEMICONDUCTOR COMPONENTS

(71) Applicant: Micron Technology, Inc., Boise, ID (US)

(72) Inventors: Amy Rae Griffin, Boise, ID (US); Brent Keeth, Boise, ID (US); Angela Tigue, Boise, ID (US)

(21) Appl. No.: 19/098,562

(22) Filed: Apr. 2, 2025

Related U.S. Application Data
(60) Provisional application No. 63/633,409, filed on Apr. 12, 2024.

(51) Int. Cl. H01L 23/373; H01L 23/00; H01L 23/48; H01L 25/18; H10B 80/00

(52) U.S. Cl. CPC H01L 23/3736; H01L 23/481; H01L 24/08; H01L 25/18; H01L 2224/08145; H10B 80/00

(57) ABSTRACT

Methods, systems, and devices for thermal vias for semiconductor components are described. A semiconductor component may be configured with conductor portions (e.g., thermal vias) that increase a degree of thermal conductivity through dielectric layers of the semiconductor component. In some examples, thermal vias may be implemented as conductor portions that are enclosed by a dielectric layer, and are therefore electrically floating relative to conductors of substrate circuitry, interconnection circuitry, or both. Additionally, or alternatively, thermal vias may be implemented as portions of conductive lines having a thickness portion that projects through at least some but not all of a respective dielectric layer. In various examples, at least some of such thermal vias may be implemented with a pitch dimension that is similar to conductive lines of one or more interconnection layers, or may implement similar processing as other features of the semiconductor component, among other implementations.

### CROSS REFERENCE

The present Application for Patent claims priority to U.S. Patent Application No. 63/633,409 by Griffin et al., entitled “THERMAL VIAS FOR SEMICONDUCTOR COMPONENTS,” filed Apr. 12, 2024, which is assigned to the assignee hereof, and which is expressly incorporated by reference in its entirety herein.

### TECHNICAL FIELD

The following relates to one or more semiconductor systems, including thermal vias for semiconductor components.

### BACKGROUND

Memory devices are used to store information in devices such as computers, user devices, wireless communication devices, cameras, digital displays, and others (e.g., host systems, processing systems). Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information (e.g., from a host system, from a processing system), a memory device may write (e.g., program, set, assign) states to the memory cells. To access stored information, a memory device may read (e.g., sense, detect, retrieve, determine) states from the memory cells, which may be provided to a requesting system (e.g., to a host system, to a processing system).

Some semiconductor systems, including memory systems, processing systems, and other systems, may experience elevated temperatures as a result of operations of the semiconductor system (e.g., related to ohmic heating or other heating associated with operating the semiconductor system). Thermal conductivity through a semiconductor system may influence an ability to transfer heat through the semiconductor system, including heat generated by operations of such a semiconductor system.

### BRIEF DESCRIPTION OF THE DRAWINGS

FIG. 1 shows an example of a system that supports thermal vias for semiconductor components in accordance with examples as disclosed herein.

FIG. 2 shows an example of a system that supports thermal vias for semiconductor components in accordance with examples as disclosed herein.

FIGS. 3 through 6 show examples of semiconductor components that support thermal vias in accordance with examples as disclosed herein.

FIGS. 7A through 7D show examples of fabrication operations that support thermal vias in accordance with examples as disclosed herein.

### DETAILED DESCRIPTION

Some semiconductor systems (e.g., memory systems, processor systems) may include a stack of semiconductor components (e.g., semiconductor dies), which may include one or more memory dies (e.g., array dies) or one or more stacks of memory dies that are stacked with a logic die that is operable to access a set of memory arrays distributed across the one or more memory dies. Such a stacked architecture may be implemented as part of a high bandwidth memory (HBM) system or a coupled dynamic random access memory (DRAM) system, among other examples, and may support solutions for memory-centric logic, such as graphics processing units (GPUs), among other implementations. In some examples, an HBM system may include one or more memory dies coupled (e.g., bonded, stacked) with a logic die. In some examples, a 3D stacked memory system may be closely coupled (e.g., physically coupled, electrically coupled, directly coupled) with a processor, such as a GPU or other host device, as part of a physical memory map accessible to the processor. A logic die may include various components such as interface blocks (e.g., memory interface blocks, interface circuitry), logic blocks, controllers, processors, and other components. A semiconductor component (e.g., a semiconductor unit, a semiconductor subsystem), such as a logic die, may be formed as a single die with relevant circuitry, or may be formed with multiple die portions (e.g., relatively smaller dies, dies each including a respective subset of components of a logic unit) that may be referred to as “chiplets” (e.g., logic chiplets), among other examples.

Some semiconductor components (e.g., dies, wafers, processing components, memory components, hybrid processor-memory components, or a combination thereof) may include substrate circuitry (e.g., transistors, capacitors, resistors, processor circuitry, memory circuitry, front end-of-line circuitry) formed at least in part from a doped portion of a semiconductor substrate (e.g., doped silicon), and interconnection circuitry (e.g., conductive lines, interconnection conductors, distribution conductors, back end-of-line circuitry) coupled with the substrate circuitry and formed in one or more layers over the semiconductor substrate. In some examples, such semiconductor components may include one or more dielectric layers between interconnection layers, or between an interconnection layer and the semiconductor substrate, or both, among other layer implementations through which conductive vias may interconnect respective conductors on either side of the via (e.g., through one or more dielectric layers). Such dielectric layers may be associated with a thickness dimension (e.g., between adjacent layers of conductors) that corresponds to a manufacturing characteristic (e.g., a deposition thickness, a deposition capability, a thickness tolerance), or a degree of isolation (e.g., a dielectric strength, an isolation tolerance, a threshold leakage resistance, a threshold capacitive coupling) between at least some conductors of adjacent layers. However, materials of such dielectric layers (e.g., dielectric materials) may have relatively a high thermal resistance (e.g., a relatively low thermal conductivity), which may limit an overall thermal conductivity through a semiconductor component and be associated with relatively high internal temperatures of the semiconductor component.

In accordance with examples as disclosed herein, a semiconductor component (e.g., a processing component, a memory component, a hybrid processor-memory component) may be configured with conductor portions (e.g., portions of conductive material), referred to herein as thermal vias, which may be implemented to increase a degree of thermal conductivity through dielectric layers of the semiconductor component (e.g., through a thickness direction of the semiconductor component relative to a substrate of the semiconductor component). In some examples, at least some of such thermal vias may be implemented as conductor portions that are enclosed by (e.g., surrounded by) a dielectric layer, and are therefore electrically floating relative to (e.g., not electrically connected with) conductors of substrate circuitry, interconnection circuitry, or both. Additionally, or alternatively, at least some of such thermal vias may be implemented as portions of conductive lines having a thickness portion that projects through at least some but not all of a respective dielectric layer (e.g., are not electrically connected with a conductive line of another interconnection layer or substrate circuitry). In various examples, at least some of such thermal vias may be implemented with a pitch dimension that is similar to (e.g., equal to) conductive lines of one or more interconnection layers, or may implement similar processing as other features of the semiconductor component (e.g., similar deposition operations, such as being formed in a dual damascene operation concurrently with conductive line formation, or similar material removal operations, such as being formed in cavities formed concurrently with cavities for conductive vias), among other implementations. Configuring a semiconductor component with such thermal vias may support reduced internal temperatures while operating the semiconductor component, or may support an increased device density (e.g., transistor density, heat density) of the semiconductor component, or both, which may support higher performance semiconductor components or assemblies (e.g., stacks) thereof.

In addition to applicability in memory systems as described herein, techniques for thermal vias for semiconductor components may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by reducing thermal resistance through semiconductor components, which may support higher-performance semiconductor components by supporting reduced internal operating temperatures and increased device densities, among other benefits.

Features of the disclosure are illustrated and described in the context of systems and architectures. Features of the disclosure are further illustrated and described in the context of semiconductor component layouts.

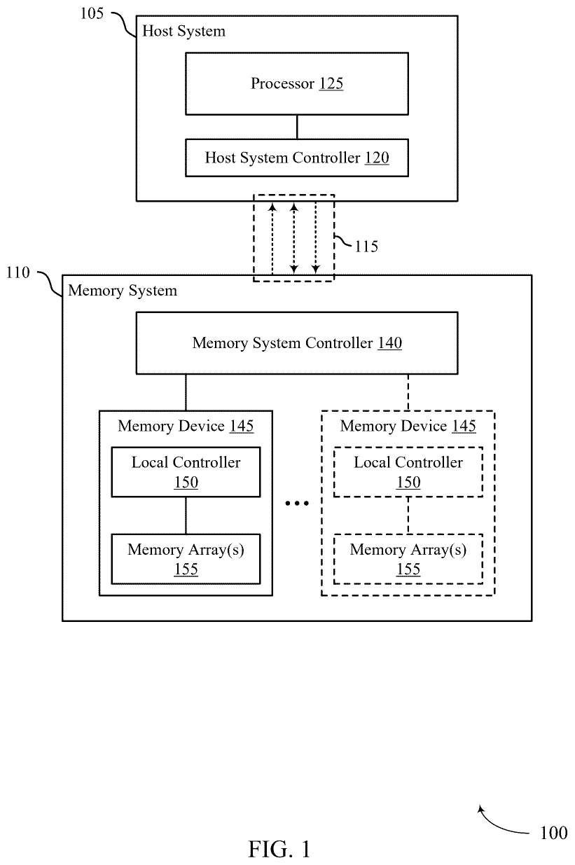

FIG. 1 shows an example of a system 100 that supports thermal vias for semiconductor components in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, application processing circuitry, one or more processing components) that use memory to execute processes (e.g., applications, functions, computations), any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

In some examples, the system 100 or the host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or a combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, portions of a memory die) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells. chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals. transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, at least a portion of the system 100 may implement a stacked semiconductor architecture in which multiple semiconductor dies are physically and communicatively coupled (e.g., directly coupled, bonded). For example, at least one of the memory arrays 155 of a memory device 145 may be formed using one or more semiconductor dies (e.g., a single memory die, a stack of multiple memory dies), which may be stacked over another semiconductor die (e.g., a logic die) that includes at least a portion of a local controller 150. In some examples, a semiconductor die or die assembly may include at least a portion of or all of a local controller 150 and at least a portion of or all of a memory system controller 140, and such a semiconductor die or die assembly may be coupled with one or more memory dies, or one or more stacks of memory dies. In accordance with these and other examples, circuitry for accessing one or more memory arrays 155 (e.g., circuitry of a memory system 110) may be distributed among multiple semiconductor dies of a stack (e.g., a stack of multiple directly-coupled semiconductor dies). For example, a first die may include a set of multiple first interface blocks (e.g., memory interface blocks, instances of first interface circuitry) and one or more second dies may include corresponding second interface blocks, each coupled with a first interface block of the first die, which are each configured to access one or more memory arrays 155 of the second dies. In some examples, the system may include a controller (e.g., a memory controller, an interface controller, a host interface controller, at least a portion of a memory system controller 140) for each set of one or more first interface blocks to support access operations (e.g., to access one or more memory arrays 155) via the set of first interface blocks. In some examples, such a controller may be located in the same first die as the first interface blocks. In some examples, multiple semiconductor dies of a memory system 110 or of a system 100 (e.g., an HBM system including aspects of a memory system 110, a stacked semiconductor system including aspects of a memory system 110 and a host system 105) may include one or more array dies stacked with a logic die (e.g., that includes aspects of the host system 105, that is coupled with another die that includes the host system 105) that includes interface blocks operable to access a set of memory arrays 155 distributed across the one or more second dies.

Some portions of a system 100 (e.g., a system 100 as a whole, a host system 105 or portion thereof, a memory system 110 or portion thereof, a memory device 145 or portion thereof) may be formed from one or more semiconductor components (e.g., wafers, dies). At least one of such semiconductor components may include substrate circuitry (e.g., transistors, capacitors, resistors, front end-of-line circuitry) formed at least in part from a doped portion of a semiconductor substrate (e.g., doped silicon), and interconnection circuitry (e.g., conductive lines, interconnection conductors, distribution conductors, back end-of-line circuitry) coupled with the substrate circuitry and formed in one or more layers over the semiconductor substrate. In some examples, such semiconductor components may include one or more dielectric layers between interconnection layers, or between an interconnection layer and the semiconductor substrate, or both, among other layer implementations through which conductive vias may interconnect respective conductors on either side of the via (e.g., through one or more dielectric layers). Such dielectric layers may be associated with a thickness dimension (e.g., between adjacent layers of conductors) that corresponds to a manufacturing characteristic (e.g., a deposition thickness, a deposition capability, a thickness tolerance), or a degree of isolation (e.g., a dielectric strength, an isolation tolerance, a threshold leakage resistance, a threshold capacitive coupling) between at least some conductors of adjacent layers. However, materials of such dielectric layers (e.g., dielectric materials) may have relatively a high thermal resistance (e.g., a relatively low thermal conductivity), which may limit an overall thermal conductivity through a semiconductor component and be associated with relatively high internal temperatures of the semiconductor component.

In accordance with examples as disclosed herein, a semiconductor component that forms at least a portion of a system 100 (e.g., a system 100 as a whole, a host system 105 or portion thereof, such as a processor 125 and/or a host system controller 120, a memory system 110 or portion thereof, a memory device 145 or portion thereof), among other semiconductor implementations, may be configured with conductor portions (e.g., portions of conductive material), referred to herein as thermal vias, which may be implemented to increase a degree of thermal conductivity through dielectric layers of the semiconductor component (e.g., through a thickness direction of the semiconductor component relative to a substrate of the semiconductor component). In some examples, at least some of such thermal vias may be implemented as conductor portions that are enclosed by (e.g., surrounded by) a dielectric layer, and are therefore electrically floating relative to (e.g., not electrically connected with) conductors of substrate circuitry, interconnection circuitry, or both. Additionally, or alternatively, at least some of such thermal vias may be implemented as portions of conductive lines having a thickness portion that projects through at least some but not all of a respective dielectric layer (e.g., are not electrically connected with a conductive line of another interconnection layer or substrate circuitry). In various examples, at least some of such thermal vias may be implemented with a pitch dimension that is similar to (e.g., equal to) conductive lines of one or more interconnection layers, or may implement similar processing as other features of the semiconductor component (e.g., similar deposition operations, such as being formed in a dual damascene operation concurrently with conductive line formation, or similar material removal operations, such as being formed in cavities formed concurrently with cavities for conductive vias), among other implementations. Configuring a semiconductor component with such thermal vias may support reduced internal temperatures while operating the semiconductor component (e.g., as a component of a system 100 or other implementation), or may support an increased device density (e.g., transistor density, heat density) of the semiconductor component, or both, which may support higher performance semiconductor components or assemblies (e.g., stacks) thereof.

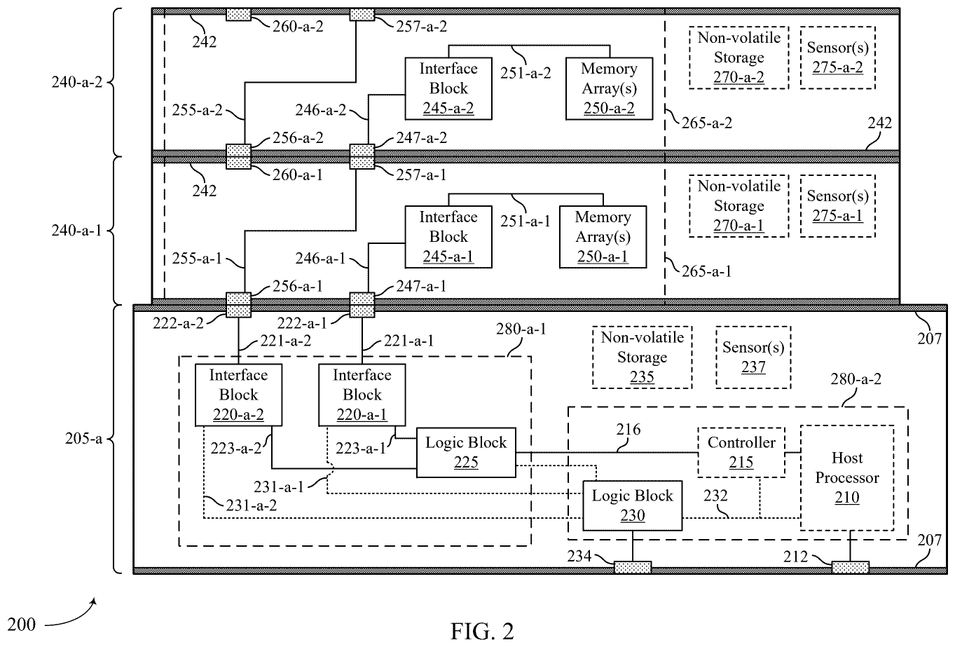

FIG. 2 shows an example of a system 200 (e.g., a semiconductor system, a system of coupled semiconductor dies, an HBM system, a 3D stacked memory system) that supports thermal vias for semiconductor components in accordance with examples as disclosed herein. The system 200 illustrates an example of a die 205 (e.g., a die 205-a, a semiconductor die, a logic die, a processor die, a host die, a logic unit) that is coupled with one or more dies 240) (e.g., dies 240-a-1 and 240-a-2, semiconductor dies, memory dies, array dies, memory units). A die 205 or a die 240, among other semiconductor components described herein may be formed using a respective semiconductor substrate (e.g., a substrate of crystalline semiconductor material such as silicon, germanium, silicon-germanium, gallium arsenide, or gallium nitride), or a silicon-on-insulator (SOI) substrate (e.g., silicon-on-glass (SOG), silicon-on-sapphire (SOS)), or epitaxial semiconductor materials formed on another substrate. among other examples. Although the illustrated example of a system 200 includes two dies 240, a system 200 in accordance with the described techniques may include any quantity of one or more dies 240 (e.g., 8, 12, 16, or more dies 240) coupled with a die 205, among other dies of a stack or other coupled layout. Further, although non-limiting examples of the system 200 herein are generally described in terms of applicability to memory systems, memory sub-systems, memory devices, or a combination thereof, examples of the system 200 are not so limited. For example, aspects of the present disclosure may be applied as well to any computing system, computing sub-system, processing system, processing sub-system, component. device, structure, or other types of systems or sub-systems used for applications such as data collecting, data processing, data storage, networking, communication, power, artificial intelligence, system-on-a-chip, control, telemetry, sensing and monitoring, digital entertainment, or any combination thereof.

The system 200 illustrates an example of interface circuitry between a host and memory (e.g., via a host interface, via a physical host interface) that is implemented in (e.g., divided between) multiple semiconductor dies (e.g., a stack of directly-coupled dies). For example, the die 205-a may include a set of one or more interface blocks 220 (e.g., interface blocks 220-a-1 and 220-a-2, memory interface blocks), and each die 240 may include a set of one or more interface blocks 245 (e.g., access interface blocks) and one or more memory arrays 250 (e.g., die 240-a-1 including an interface block 245-a-1 coupled with a set of one or more memory arrays 250-a-1, die 240-a-2 including an interface block 245-a-2 coupled with a set of one or more memory arrays 250-a-2). The memory arrays 250 may be examples of memory arrays 155, and may include memory cells of various architectures, such as RAM, DRAM, SDRAM, SRAM, FeRAM, MRAM, RRAM, PCM, chalcogenide, NOR, or NAND memory cells, or any combination thereof.

Although the example of system 200 is illustrated with one interface block 245 included in each die 240, a die 240 in accordance with the described techniques may include any quantity of one or more interface blocks 245, each coupled with a respective set of one or more memory arrays 250, and each coupled with an interface block 220 of a die 205. Thus, the interface circuitry of a system 200 may include one or more interface blocks 220 of a die 205, with each interface block 220 being coupled with (e.g., in communication with) one or more interfaces block 245 of a die 240 (e.g., external to the die 205). In some examples, a coupled combination of an interface block 220 and an interface block 245 (e.g., coupled via a bus associated with one or more channels, such as one or more data channels, one or more control channels, one or more clock channels, one or more pseudo-channels, or a combination thereof) may include or be referred to as a data path associated with a respective set of one or more memory arrays 250.

In some implementations, a die 205 may include a host processor 210. A host processor 210 may be an example of a host system 105, or a portion thereof (e.g., a processor 125, aspects of a host system controller 120, or both). The host processor 210 may be configured to perform operations that implement storage of the memory arrays 250 (e.g., to support an application or other function of a host system 105, which may request access of the memory arrays 250). For example, the host processor 210 may receive data read from the memory arrays 250, or may transmit data to be written to the memory arrays 250, or both (e.g., in accordance with an application or other operations of the host processor 210). Additionally, or alternatively, a host processor 210 may be external to a die 205 (e.g., in HBM implementations), such as in another semiconductor die or other component that is coupled with (e.g., communicatively coupled with, directly coupled with, bonded with, coupled via another intervening component) the die 205 via one or more contacts 212 (e.g., externally-accessible terminals of the die 205).

A host processor 210 may be configured to communicate (e.g., transmit, receive) signaling with interface blocks 220 via a host interface 216 (e.g., a physical host interface), which may implement aspects of channels 115. For example, a host interface 216 may be configured in accordance with an industry standard, which may define channels, commands, clocking, and deterministic responses and timing, among other characteristics of the host interface 216. In some examples, a host interface 216 may provide a communicative coupling between physical or functional boundaries of a host system 105 and a memory system 110. For example, the host processor 210 may be configured to communicate access signaling (e.g., control signaling, access command signaling, data signaling, configuration signaling, clock signaling) via a host interface 216 to support access operations (e.g., read operations, write operations) on the memory arrays 250, among other operations. Although the example of system 200 includes a single host interface 216, a system in accordance with the described techniques may include any quantity of one or more host interfaces 216 for accessing memory arrays 250 of the system.

In some examples, a respective host interface 216 may be coupled between a set of one or more interface blocks 220 (e.g., interface blocks 220-a-1 and 220-a-2) and a respective controller 215. A controller 215 may be an example of control circuitry (e.g., memory controller circuitry, host interface control circuitry) associated with a host system 105, and may be associated with implementing respective instances of one or more aspects of a host system controller 120, or of a memory system controller 140, or a combination thereof. For example, a controller 215 may be operable to respond to indications (e.g., requests, commands) from the host processor 210 to access one or more memory arrays 250 in support of a function or application of the host processor 210, to transmit associated commands (e.g., for one or more interface blocks 220) to access the one or more memory arrays 250, and to communicate data (e.g., write data, read data) with the host processor 210, among other functions.

In some examples, one or more controllers 215 may be implemented in a die 205 (e.g., the same die that includes one or more interface blocks 220, in a 3D stacked memory implementation) (e.g., in accordance with a command and address protocol) whether a host processor 210 is included in the die 205, or is external to the die 205. In some other examples, controllers 215 or associated circuitry or functionality may be implemented external to a die 205 (e.g., in another die, not shown, coupled with respective interface blocks 220 via respective terminals for each of the respective host interfaces 216, in an HBM implementation), which may be in the same die as or a different die from a die that includes a host processor 210. An interface block 220 may be operable via a single controller 215, or by one or more of a set of multiple controllers 215 (e.g., in accordance with a controller multiplexing scheme). In some other examples, aspects of one or more controllers 215 may be included in the host processor 210 (e.g., as a memory interface of the host processor 210, as a memory interface of a host system 105).

Although, in some examples, a controller 215 may be directly coupled with one or more interface blocks 220 (not shown), in some other examples, a controller 215 (e.g., a host interface 216) may be coupled with a set of multiple interface blocks 220 via a logic block 225 (e.g., logic circuitry for a channel set, logic circuitry for a host interface 216, multiplexing circuitry). For example, the logic block 225 may be coupled with the interface block 220-a-1 via a bus 223-a-1 and coupled with the interface block 220-a-2 via a bus 223-a-2. A controller 215 and one or more corresponding interface blocks 220 and may communicate (e.g., collaborate) using the host interface 216 via a logic block 225 to perform one or more operations (e.g., scheduling operations, access operations, operations initiated by a host processor 210) associated with accessing a corresponding set of one or more memory arrays 250.

In some examples, a logic block 225, a controller 215, or a host interface 216, or a combination thereof may be associated with a “channel set” that corresponds to multiple memory array's 250 (e.g., for parallel or otherwise coordinated access of the multiple memory arrays 250). For example, such a channel set may be associated with multiple memory array's 250 accessed via a single interface block 245, or multiple memory arrays 250 each accessed via a respective one of the interface blocks 245, or multiple memory arrays 250 each accessed via a respective one of the interface blocks 220, any of which may be associated with signaling via a single logic block 225, via a single host interface 216, or via a single controller 215. These and other configurations for implementing one or more channel sets in a system may support various techniques for parallelism and high bandwidth data transfer, memory management operations, repair and replacement techniques, or power and thermal distribution, among other techniques that leverage the described coupling of components and interfaces among multiple semiconductor dies (e.g., in accordance with a high bandwidth configuration of the system 200, in accordance with a closely-coupled configuration of the system 200). In some examples, such techniques may be implemented (e.g., at or using a logic block 225) in a manner that is transparent to the host interface 216 or other aspects of a host system 105.

In some examples, a host interface 216 may include a respective set of one or more signal paths for each logic block 225 or interface block 220, such that the host processor 210 may communicate with each logic block 225 or interface block 220 via its corresponding set of signal paths (e.g., in accordance with a selection of the corresponding set to perform access operations via a logic block 225 or interface block 220 that is selected by the host processor 210). Additionally, or alternatively, a host interface 216 may include one or more signal paths that are shared among multiple logic blocks 225 (not shown) or interface blocks 220, and a logic block 225, an interface block 220, or a host processor 210, or any of these may interpret, ignore, respond to, or inhibit response to signaling via shared signal paths of the host interface 216 based on a logical indication (e.g., an addressing indication associated with the logic block 225 or interface block 220, an interface enable signal, or an interface select signal, which may be provided by the host processor 210, the corresponding logic block 225, or the corresponding interface block 220 depending on signaling direction).

In some examples, a host processor 210 may determine to access an address (e.g., a logical address of a memory array 250, a physical address of a memory array 250, an address of a logic block 225, an address of an interface block 220, an address of a host interface 216, in response to an application of or supported by the host processor 210), and determine which controller 215 to transmit access signaling to for accessing the address (e.g., a controller 215, logic block 225, or interface block 220 corresponding to the address). In some examples, the address may be associated with a row of memory cells of the memory array 250, a column of memory cells of the memory array 250, or both. The host processor 210 may transmit access signaling (e.g., one or more access signals, one or more access commands) to the determined controller 215 and, in turn, the determined controller 215 may transmit access signaling to the corresponding logic block 225 or interface block 220 (e.g., in accordance with a command and address protocol). The corresponding interface block 220 may subsequently transmit access signaling to the coupled interface block 245 to access the determined address (e.g., of a corresponding memory array 250).

A die 205 may also include a logic block 230 (e.g., a shared logic block, a central logic block, common logic circuitry, evaluation circuitry, memory system configuration circuitry, memory system management circuitry), which may be configured to communicate (e.g., transmit, receive) signaling with the logic blocks 225, the interface blocks 220, or both of the die 205. In some cases, a logic block 230 may be configured to communicate information (e.g., commands, instructions, indications, data) with one or more logic blocks 225 or interface blocks 220 to facilitate operations of the system 200. For example, a logic block 230 may be configured to transmit configuration signaling (e.g., initialization signaling, evaluation signaling, mapping signaling), which may be received by logic blocks 225 or interface blocks 220 to support configuration of the logic blocks 225 or interface blocks 220, or other aspects of operating the dies 240 (e.g., via the respective interface blocks 245). A logic block 230 may be coupled with each logic block 225 and each interface block 220 via a respective bus 231. In some examples, such buses may each include a respective set of one or more signal paths, such that a logic block 230 may communicate with each logic block 225 or each interface block 220 via the respective set of signal paths. Additionally, or alternatively, such buses may include one or more signal paths that are shared among multiple logic blocks 225 or interface blocks 220 (not shown).

In some implementations, a logic block 230 may be configured to communicate (e.g., transmit, receive) signaling with a host processor 210 or one or more controllers 215 (e.g., via a bus 232, via a contact 212 for a host processor 210 or controller 215 external to a die 205), such that the logic block 230 may support an interface between the host processor 210 or one or more controllers 215 and the logic blocks 225 or interface blocks 220. For example, a host processor 210 or a controller 215 may be configured to transmit initialization signaling (e.g., boot commands), or other configuration or operational signaling, which may be received by a logic block 230 to support initialization, configuration, evaluation, or other operations of the logic blocks 225 or interface blocks 220. Additionally, or alternatively, in some implementations, a logic block 230 may be configured to communicate (e.g., transmit, receive) signaling with a component outside the system 200 (e.g., via a contact 234, which may be an externally-accessible terminal of the die 205), such that the logic block 230 may support an interface that bypasses a host processor 210 or controller 215. Additionally, or alternatively, a logic block 230 may communicate with a host processor 210 or a controller 215, and may communicate with one or more memory arrays 250 of one or more dies 240 (e.g., to perform self-test operations for access of memory arrays 250). In some examples, such implementations may support evaluations, configurations, or other operations of the system 200, via one or more contacts 234 that are accessible at a physical interface of the system, during manufacturing, assembly, validation, or other operation associated with the system 200 (e.g., before coupling with a host processor 210, without implementing a host processor 210, for operations independent of a host processor). Additionally, or alternatively, a logic block 230 may implement one or more aspects of a controller 215. For example, a logic block 230 may include or operate as one or more controllers 215 and may perform operations ascribed to a controller 215.

In some examples, respective signals may be routed between a die 205 die and one or more dies 240. For example, each interface block 220 may be coupled with at least a respective bus 221 of the die 205, and a respective bus 246 of a die 240, that are configured to communicate signaling with a corresponding interface block 245 (e.g., via one or more associated signal paths). For example, the interface block 220-a-1 may be coupled with the interface block 245-a-1 via a bus 221-a-1 and a bus 246-a-1, and the interface block 220-a-2 may be coupled with the interface block 245-a-2 via a bus 221-a-2 and a bus 246-a-2. In some examples, a die 240 may include a bus that bypasses operational circuitry of the die 240 (e.g., that bypasses interface blocks 245 of a given die 240), such as a bus 255. For example, the interface block 220-a-2 may be coupled with the interface block 245-a-2 of the die 240-a-2 via a bus 255-a-1 of the die 240-a-1, which may bypass interface blocks 245 of the die 240-a-1. Such techniques may be extended for interconnection among more than two dies 240 (e.g., for interconnection via a respective bus 255 of multiple dies 240). In some implementations, at least a portion of a bus 221, a bus 246, or a bus 255, or any combination thereof may include one or more conductors in a redistribution layer (RDL) of a respective die (e.g., above or below a semiconductor substrate of the die). Additionally, or alternatively, in some implementations, at least a portion of a bus 221, a bus 246, or a bus 255, or any combination thereof may include one or more vias that are formed through a semiconductor substrate of a respective die (e.g., as one or more through-silicon vias (TSVs)).

The respective signal paths of buses 221, 246, and 255 may be coupled with one another, from one die to another, via various arrangements of contacts at the surfaces of interfacing dies (e.g., exposed contacts, metal surfaces of the respective dies). For example, the bus 221-a-1 may be coupled with the bus 246-a-1 via a contact 222-a-1 of (e.g., at a surface of) the die 205-a and a contact 247-a-1 of the die 240-a-1, the bus 221-a-2 may be coupled with the bus 255-a-1 via a contact 222-a-2 of the die 205 and a contact 256-a-1 of the die 240-a-1. the bus 255-a-1 may be coupled with the bus 246-a-2 via a contact 257-a-1 of the die 240-a-1 and a contact 247-a-2 of the die 240-a-2, and so on. Although each respective bus is illustrated with a single line, coupled via singular contacts, it is to be understood that each signal path of a given bus may be associated with respective contacts to support a separate communicative coupling via each signal path of the given bus. In some examples, a bus 255 may traverse a portion of a die 240 (e.g., in an in-plane direction, along a direction different from a thickness direction, in a waterfall arrangement, in a staircase arrangement), which may support an arrangement of contacts 222 along a surface of a die 205, among other contacts, being coupled with interface blocks 245 of different dies 240 along a stack direction (e.g., via respective contacts 256 and 257 that are non-overlapping when viewed along a thickness direction).

The interconnection of interfacing contacts may be supported by various techniques. For example, in a hybrid bonding implementation, interfacing contacts may be coupled by a fusion of conductive materials (e.g., electrically conductive materials) of the interfacing contacts (e.g., without solder or other intervening material between contacts). For example, in an assembled condition, the coupling of the die 205-a with the die 240-a-1 may include a conductive material of the contact 222-a-2 being fused with a conductive material of the contact 256-a-1, and the coupling of the die 240-a-1 with the die 240-a-2 may include a conductive material of the contact 257-a-1 being fused with a conductive material of the contact 247-a-2, and so on. In some examples, such coupling may include an inoperative fusion of contacts (e.g., a non-communicative coupling, a physical coupling), such as a fusion of the contact 260-a-1 with the contact 256-a-2, neither of which are coupled with operative circuitry of the dies 240-a-1 or 240-a-2. In some examples, such techniques may be implemented to improve coupling strength or uniformity (e.g., implementing contacts 260, which may not be operatively coupled with an interface block 245 or an interface block 220), or such a coupling may be a byproduct of a repetition of components that, in various configurations, may be operative or inoperative. (e.g., where, for dies 240 with a common arrangement of contacts 256 and 257, contacts 256-a-1 and 257-a-1 provide a communicative path between the interface block 245-a-2 and the interface block 220-a-2, but the contacts 256-a-2 and 257-a-2 do not provide a communicative path between an interface block 245 and an interface block 220).

In some examples, a fusion of conductive materials between dies (e.g., between contacts) may be accompanied by a fusion of other materials at one or more surfaces of the interfacing dies. For example, in an assembled condition, the coupling of the die 205 with the die 240-a-1 may include a dielectric material 207 (e.g., an electrically non-conductive material) of the die 205-a being fused with a dielectric material 242 of the die 240-a-1, and the coupling of the die 240-a-1 with the die 240-a-2 may include a dielectric material 242 of the die 240-a-1 being fused with a dielectric material 242 of the die 240-a-2. In some examples, such dielectric materials may include an oxide, a nitride, a carbide, an oxide-nitride, an oxide-carbide, or other conversion or doping of a substrate material (e.g., a semiconductor substrate material) or other material of the die 205 or dies 240, among other materials that may support such fusion. However, coupling among dies 205 and dies 240 may be implemented in accordance with other techniques, which may implement solder, adhesives, thermal interface materials, and other intervening materials or combinations of materials.

In some examples, dies 240 may be coupled in a stack (e.g., forming a “cube” or other arrangement of dies 240), and one or more of such stacks may subsequently be coupled with a die 205 (e.g., in a stack-to-chip bonding arrangement). In some examples, respective set(s) of one or more dies 240 may be coupled with each die 205 of multiple dies 205 as formed in a wafer (e.g., in a chip-to-wafer bonding arrangement, in a stack-to-wafer bonding arrangement, before cutting the wafer of dies 205), and the dies 205 of the wafer, each coupled with their respective set(s) of dies 240, may be separated from one another (e.g., by cutting at least the wafer of dies 205, by singulation). In some other examples, respective set(s) of one or more dies 240 may be coupled with a respective die 205 after the die 205 is separated from a wafer of dies 205 (e.g., in a chip-to-chip bonding arrangement). In some other examples, a respective set of one or more wafers, each including multiple dies 240, may be coupled in a stack (e.g., in a wafer-to-wafer bonding arrangement). In various examples, such techniques may be followed by separating stacks of dies 240 from the coupled wafers, or the stack of wafers having dies 240 may be coupled with another wafer including multiple dies 205 (e.g., in a second wafer-to-wafer bonding arrangement), which may be followed by separating systems 200 from the coupled wafers. In some other examples, wafer-to-wafer coupling techniques may be implemented by stacking one or more wafers of dies 240 (e.g., sequentially) over a wafer of dies 205 before separation into systems 200, among other examples for forming systems 200.

The buses 221, 246, and 255 may be implemented to provide a configured signaling (e.g., a coordinated signaling, a logical signaling, modulated signaling, digital signaling) between an interface block 220 and a corresponding interface block 245, which may involve various modulation or encoding techniques by a transmitting interface block (e.g., via a driver component of the transmitting interface block). In some examples, such signaling may be supported by (e.g., accompanied by) clock signaling communicated via the respective buses (e.g., in coordination with signal transmission). For example, the buses may be configured to convey one or more clock signals transmitted by the interface block 220 for reception by the interface block 245 (e.g., to trigger signal reception by a latch or other reception component of the interface block 245, to support clocked operations of the interface block 245). Additionally, or alternatively, the buses may be configured to convey one or more clock signals transmitted by the interface block 245 for reception by the interface block 220 (e.g., to trigger signal reception by a latch or other reception component of the interface block 220, to support clocked operations of the interface block 220). Such clock signals may be associated with the communication (e.g., unidirectional communication, bidirectional communication, deterministic communication) of various signaling, such as control signaling. command signaling. data signaling, or any combination thereof. For example, the buses may include one or more signal paths for communications of a data bus (e.g., one or more data channels, a DQ bus, via a data interface of the interface blocks) in accordance with one or more corresponding clock signals (e.g., data clock signals), or one or more signal paths for communications of a control bus (e.g., a command/address (C/A) bus, via a command interface of the interface blocks) in accordance with one or more clock signals (e.g., control clock signals), or any combination thereof.

Interface blocks 220, interface blocks 245, logic blocks 225, and a logic block 230 each may include circuitry (signaling circuitry, multiplexing circuitry, processing circuitry, controller circuitry, logic circuitry, physical components, hardware) in various configurations (e.g., hardware configurations, logic configurations, software or instruction configurations) that support the functionality allocated to the respective block for accessing or otherwise operating a corresponding set of memory arrays 250. For example, interface blocks 220 may include circuitry configured to perform a first subset of operations that support access of the memory arrays 250, and interface blocks 245 may include circuitry configured to perform a second subset of operations that support access of the memory arrays 250. In some examples. the interface blocks 220, the interface blocks 245, and logic blocks 225 may support a functional split or distribution of functionality associated with a memory system controller 140, a local controller 150, or both across multiple dies (e.g., a die 205 and at least one die 240). In some implementations, a logic block 230 may be configured to coordinate or configure aspects of the operations of the interface blocks 220, of the interface blocks 245, of the logic blocks 225, or a combination thereof, and may support implementing one or more aspects of a memory system controller 140. Such operations, or subsets of operations, may include operations performed in response to commands from the host processor 210 or a controller 215, or operations performed without commands from a host processor 210 or a controller 215 (e.g., operations determined by or initiated by a logic block 225, operations determined by or initiated by an interface block 220, operations determined by or initiated by an interface block 245, operations determined by or initiated by a logic block 230), or various combinations thereof.

In some implementations, the system 200 may include one or more instances of non-volatile storage (e.g., non-volatile storage 235 of a die 205, non-volatile storage 270 of one or more dies 240, or a combination thereof). In some examples, a logic block 230, logic blocks 225, interface blocks 220, interface blocks 245, or a combination thereof may be configured to communicate signaling with one or more instances of non-volatile storage. For example, a logic block 230, logic blocks 225, interface blocks 220, or interface blocks 245 may be coupled with one or more instances of non-volatile storage via one or more buses (not shown), or respective contacts (not shown), where applicable, which may each include one or more signal paths operable to communicate signaling (e.g., command signaling, data signaling). In some examples, a logic block 230, one or more logic blocks 225, one or more interface blocks 220, one or more interface blocks 245, or a combination thereof may configure one or more operations based on information (e.g., instructions, configurations, parameters) stored in one or more instances of non-volatile storage. Additionally, or alternatively, in some examples, a logic block 230, one or more logic blocks 225, one or more interface blocks 220, one or more interface blocks 245, or a combination thereof may write information (e.g., configuration information, evaluation information) to be stored in one or more instances of non-volatile storage. In some examples, such non-volatile storage may include fuses, antifuses, or other types of one-time programmable storage elements, or any combination thereof.

In some implementations, the system 200 may include one or more sensors (e.g., one or more sensors 237 of a die 205, one or more sensors 275 of one or more dies 240, or a combination thereof). In some implementations, a logic block 230, logic blocks 225, interface blocks 220, interface blocks 245, or a combination thereof may be configured to receive one or more indications based on measurements of one or more sensors of the system 200. For example, a logic block 230, logic blocks 225, interface blocks 220, or interface blocks 245 may be coupled with one or more sensors via one or more buses (not shown), or respective contacts (not shown). Such sensors may include temperature sensors, current sensors, voltage sensors, counters, and other types of sensors. In some examples, a logic block 230, one or more logic blocks 225, one or more interface blocks 220, one or more interface blocks 245, or a combination thereof may configure one or more operations based on output of the one or more sensors. For example, a logic block 230 may configure one or more operations of logic blocks 225 or interface blocks 220 based on signaling (e.g., indications, data) received from the one or more sensors. Additionally, or alternatively, a logic block 225 or an interface block 220) may generate access signaling for transmitting to a corresponding interface block 245 based on one or more sensors.

In some examples, circuitry of logic blocks 225, interface blocks 220, interface blocks 245, or a logic block 230, or any combination thereof may include components (e.g., transistors) formed at least in part from doped portions of a substrate of the respective die. In some examples, a substrate of a die 205 may have characteristics (e.g., materials, material characteristics, physical shapes or dimensions) that are different from those of a substrate of a die 240). Additionally, or alternatively, in some examples, transistors formed from a substrate of a die 205 may have characteristics (e.g., manufacturing characteristics, performance characteristics, physical shapes or dimensions) that are different from transistors formed from a substrate of a die 240) (e.g., in accordance with different transistor architectures, in accordance with different transistor designs).

In some examples, the interface blocks 220 may support a layout for one or more components within the interface blocks 220. For example, the layout may include pairing components to share an access port (e.g., a command port, a data port). Further, in some examples, the layout may support interfaces for a controller 215 (e.g., a host interface 216) that are different from interfaces for an interface block 245 (e.g., via the buses 221). For instance, a host interface 216 may be synchronous and have separate channels for read and write operations, while an interface between an interface block 220 and one or more interface blocks 245 may be asynchronous and support both read and write operations with the same channel. In some examples, signaling of a host interface 216 may be implemented with a deterministic timing (e.g., deterministic between a controller 215 and a logic block 225 or one or more interface blocks 220), which may be associated with a configured timing between a first signal and a responsive second signal. In some examples, signaling between an interface block 220 and one or more interface blocks 245 may be implemented with a timing that is different from timing of a host interface 216 (e.g., in accordance with a different clock frequency, in accordance with a timing offset, such as a phase offset), which may be deterministic or non-deterministic.

A die 240 may include one or more units 265 (e.g., modules) that are separated from a semiconductor wafer having a pattern (e.g., a two-dimensional pattern) of units 265. Although each die 240 of the system 200 is illustrated with a single unit 265 (e.g., unit 265-a-1 of die 240-a-1, unit 265-a-2 of die 240-a-2), a die 240 in accordance with the described techniques may include any quantity of units 265, which may be arranged in various patterns (e.g., sets of one or more units 265 along a row direction, sets of one or more units 265 along a column direction, among other patterns). Each unit 265 may include at least the circuitry of a respective interface block 245, along with memory array(s) 250, a bus 251, a bus 246, and one or more contacts 247 corresponding to the respective interface block 245. In some examples, where applicable, each unit 265 may also include one or more buses 255, contacts 256, contacts 257, or contacts 260 (e.g., associated with a respective interface block 245 of a unit 265 of a different die 240), which may support various degrees of stackability or modularity among or via units 265 of other dies 240. Although examples of non-volatile storage 270 and sensors 275 are illustrated outside units 265, in some other examples, non-volatile storage 270, sensors 275, or both may additionally, or alternatively, be included in units 265.

In some examples, the interface blocks 220 may include circuitry configured to receive first access command signaling (e.g., from a host processor 210, from a controller 215, from a logic block 225, via a host interface 216, via one or more contacts 212 from a host processor 210 or controller 215 external to a die 205, based on a request from a host application), and to transmit second access command signaling to the respective (e.g., coupled) interface block 245 based on (e.g., in response to) the received first access command signaling. The interface blocks 245 may accordingly include circuitry configured to receive the second access command signaling from the respective interface block 220 and. in some examples, to access a respective set of one or more memory arrays 250 based on (e.g., in response to) the received second access command signaling. In various examples, the first access command signaling may include access commands that are associated with a type of operation (e.g., a read operation, a write operation, a refresh operation, a memory management operation), which may be associated with an indication of an address of the one or more memory arrays 250) (e.g., a logical address, a physical address). In some examples, the first access command signaling may include an indication of a logical address associated with the memory arrays 250, and circuitry of an interface block 220 may be configured to generate the second access command signaling to indicate a physical address associated with the memory arrays 250 (e.g., a row address, a column address, using a logical-to-physical (L2P) table or other mapping or calculation functionality of the interface block 220).

In some examples, to support write operations of the system 200, circuitry of the interface blocks 220 may be configured to receive (e.g., from a host processor 210, from a controller 215, from a logic block 225) first data signaling associated with the first access command signaling, and to transmit second data signaling (e.g., associated with second access command signaling) based on received first access command signaling and first data signaling. The interface blocks 245 may accordingly be configured to receive second data signaling, and to write data to one or more memory arrays 250) (e.g., in accordance with an indicated address associated with the first access command signaling) based on the received second access command signaling and second data signaling. In some examples, the interface blocks 220 may include an error control functionality (e.g., error detection circuitry, error correction circuitry, error correction code (ECC) logic, an ECC engine) that supports the interface blocks 220 generating the second data signaling based on performing an error control operation using the received first data signaling (e.g., detecting or correcting an error in the first data signaling, determining one or more parity bits to be conveyed in the second data signaling and written with the data).

In some examples, to support read operations of the system 200, circuitry of the interface blocks 245 may be configured to read data from the memory arrays 250 based on received second access command signaling, and to transmit first data signaling based on the read data. The interface blocks 220 may accordingly be configured to receive first data signaling, and to transmit second data signaling (e.g., to a host processor 210), to a controller 215, to a logic block 225) based on the received first data signaling. In some examples, the interface blocks 220 may include an error control functionality that supports the interface blocks 220 generating the second data signaling based on performing an error control operation using the received first data signaling (e.g., detecting or correcting an error in the first data signaling, which may include a calculation involving one or more parity bits received with the first data signaling).

In some examples, access command signaling that is transmitted to the interface blocks 245, among other signaling, may be generated (e.g., based on access command signaling received from a host processor 210, based on initiation signaling received from a host processor 210, without receiving or otherwise independent from signaling from a host processor 210) in accordance with various determination or generation techniques configured at the interface blocks 220 or the logic blocks 225 (e.g., based on a configuration for accessing memory arrays 250 that is modified at the interface blocks 220 or the logic blocks 225). In some examples, such techniques may involve signaling or other coordination with a logic block 230, a logic block 225, a host processor 210, one or more controllers 215, one or more instances of non-volatile storage, one or more sensors, or any combination thereof. Such techniques may support the interface blocks 220 or logic blocks 225 configuring aspects of the access operations performed on the memory arrays 250 by a respective interface block 245, among other operations. For example, interface blocks 220 or logic blocks 225 may include evaluation circuitry, access configuration circuitry, signaling circuitry, scheduling circuitry, repair circuitry, refresh circuitry, error control circuitry, adverse access (e.g., row hammer) mitigation circuitry, and other circuitry operable to configure operations associated with one or more dies (e.g., operations associated with accessing memory arrays 250 of the dies 240).

In some examples, functionality of a die 205 may be implemented as a semiconductor unit (e.g., a semiconductor system) that is formed with multiple semiconductor die portions (e.g., semiconductor chiplets, relatively smaller semiconductor dies), and each die portion may include respective portions of circuitry associated with the die 205. For example, a unit 280 may represent a portion of the circuitry components included in a die portion (e.g., in a chiplet), and the die portion may include an integer multiple of units 280. In some examples, each semiconductor die portion of a semiconductor unit may include different respective portions of circuitry. As a non-limiting example, a semiconductor unit (e.g., having the functionality of a die 205) may be formed by one or more first die portions having one or more units 280-a-1 and one or more second die portions having one or more units 280-a-2. The one or more units 280-a-1 may include one or more interface blocks 220, a logic block 225, or any combination thereof, and the one or more units 280-a-2 may include a host processor 210, one or more controllers 215, a logic block 230, or any combination thereof.

In accordance with examples as disclosed herein, a die 205, one or more dies 240, or a combination thereof may be configured with conductor portions that increase a degree of thermal conductivity through dielectric layers of the respective die. In some examples, at least some of such thermal vias may be implemented as conductor portions that are enclosed by a dielectric layer, and are therefore electrically floating relative to conductors of substrate circuitry, interconnection circuitry, or both. Additionally, or alternatively, at least some of such thermal vias may be implemented as portions of conductive lines having a thickness portion that projects through at least some but not all of a respective dielectric. Configuring a die 205, one or more dies 240, or a combination thereof with such thermal vias may support reduced internal temperatures while operating a system 200, or may support an increased device density (e.g., transistor density, heat density) of the respective die, or both, which may support higher performance systems 200.

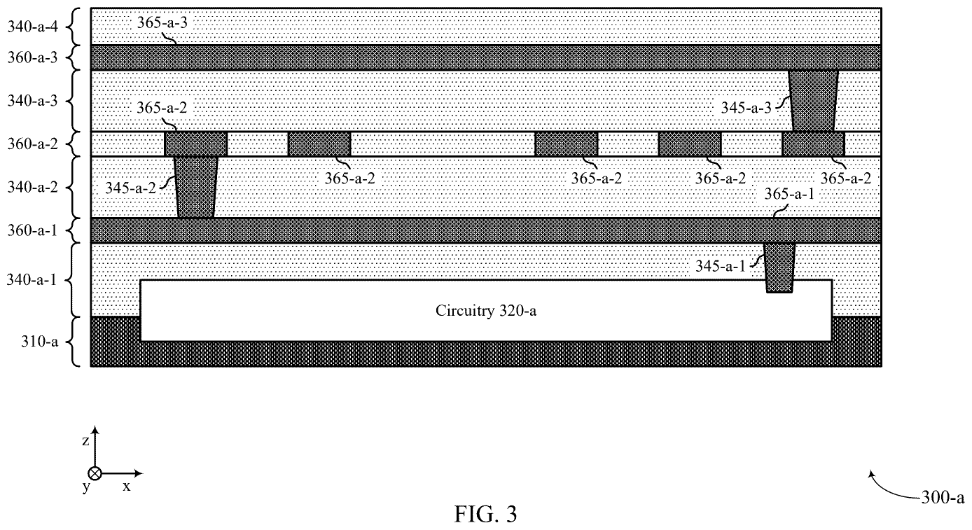

FIG. 3 shows an example of a semiconductor component 300-a that supports thermal vias in accordance with examples as disclosed herein. A semiconductor component 300, or a combination of multiple semiconductor components 300 (e.g., as an assembly of multiple semiconductor components, as a stack of semiconductor components 300) may illustrate examples for implementing aspects of a system 100 or system 200, among other semiconductor component implementations. For example, one or more instances of a semiconductor component 300 may be implemented in a host system 105 or a portion thereof (e.g., one or more semiconductor components 300 of a processor 125, one or more semiconductor components 300 of a host system controller 120), a memory system 110 or a portion thereof (e.g., one or more semiconductor components 300 of a memory device 145, one or more semiconductor components 300 of a memory system controller 140). In some examples, one or more semiconductor components 300 may be implemented as a die 205, or a die 240, or a combination thereof (e.g., in an HBM implementation, in a 3D stacked memory implementation). Aspects of the semiconductor component 300-a may be described with reference to an x-direction (e.g., a first direction over a substrate 310), a y-direction (e.g., a second direction over a substrate 310), and a z-direction (e.g., a direction from a substrate 310) of the illustrated coordinate system, with the illustration of FIG. 3 depicting aspects of the semiconductor component 300-a in an xz-plane (e.g., a cross-sectional plane) that may extend for some distance along the y-direction.

The semiconductor component 300-a includes a substrate 310-a (e.g., a semiconductor substrate). A substrate 310 may be a substrate of crystalline semiconductor material, such as silicon, germanium, silicon-germanium, gallium arsenide, gallium nitride, or other semiconductor materials. In some examples, a substrate 310 may include or a silicon-on-insulator (SOI) substrate (e.g., silicon-on-glass (SOG), silicon-on-sapphire (SOS)), or epitaxial semiconductor materials formed on another substrate, among other examples.

The semiconductor component 300-a also includes circuitry 320-a (e.g., substrate circuitry, FEOL circuitry). Circuitry 320 may include various circuit elements such as transistors, capacitors, resistors, inductors, and other circuit elements (e.g., operable circuit elements, processing circuitry, access circuitry, signaling circuitry). Circuitry 320, such as transistors and other semiconductor components of the circuitry 320, may be formed at least in part from a doped portion of a substrate 310 (e.g., one or more p-doped portions, one or more n-doped portions, or a combination thereof). A semiconductor component 300 may also include one or more memory arrays (e.g., memory arrays 155, memory arrays 250), which may be included in circuitry 320 or coupled with circuitry 320, and at least a portion of the circuitry 320 may, in some examples, be configured for accessing the one or more memory arrays.

The semiconductor component 300-a also includes interconnection layers 360-a (e.g., interconnection layers 360-a-1, 360-a-2, and 360-a-3) and dielectric layers 340-a (e.g., adjacent dielectric layers, dielectric layer 340-a-1 between the interconnection layer 360-a-1 and the substrate 310-a and circuitry 320-a, dielectric layer 340-a-2 between the interconnection layers 360-a-1 and 250-a-2, dielectric layer 340-a-3 between the interconnection layers 360-a-2 and 360-a-3, dielectric layer 340-a-4 over the interconnection layer 360-a-3). In some examples, at least a portion of the interconnection layers 360 and dielectric layers 340 of a semiconductor component 300 may be referred to as BEOL circuitry, which may be formed after (e.g., over) FEOL circuitry. In the example of semiconductor component 300-a, each of the interconnection layers 360 may be arranged on (e.g., located along, along the positive z-direction from) a same side of the substrate 310-1 that is doped to form the circuitry 320-a (e.g., a front side, as front-side interconnection layers 360). Additionally, or alternatively, a semiconductor component 300 in accordance with the described techniques may include one or more interconnection layers 360 that are arranged on an opposite side of a substrate 310 that is doped to form circuitry 320 (e.g., a back side, as back-side interconnection layers 360).

Interconnection layers 360 may each include respective conductive lines 365 (e.g., conductive traces, routing traces, interconnection lines) that extend along one or more directions in the respective interconnection layer 360 (e.g., one or more directions in an xy-plane). For example, the interconnection layer 360-a-1 may include one or more conductive lines 365-a-1 that extend at least partially along (e.g., provide a conductive path along, provide an electrical connection along) the x-direction, the interconnection layer 360-a-2 may include one or more conductive lines 365-a-2 that extend at least partially along the z-direction, and the interconnection layer 360-a-3 may include one or more conductive lines 365-a-3 that extend at least partially along the x-direction. Although the example of semiconductor component 300-a includes three interconnection layers 360, a semiconductor component 300 in accordance with the described techniques may include any quantity of one or more interconnection layers 360, which may each include various implementations of conductive lines 365 along one or more directions in an xy-plane within the respective interconnection layer 360. Each of the conductive lines 365 may include one or more conductive materials, such as copper, tungsten, gold, silver, and other conductive materials.

Dielectric layers 340 may each include one or more dielectric materials that provide a degree of electrical isolation between adjacent layers or components (e.g., between at least some conductive lines 365 of different interconnection layers 360, between at least some conductive lines 365 and circuitry 320). A semiconductor component 300 may also include at least some vias 345 that extend through a given dielectric layer 340 (e.g., through one or more dielectric layers 340). For example, a via 345-a-1 may couple one of the conductive lines 365-a-1 with the circuitry 320-a through the dielectric layer 340-a-1, a via 345-a-2 may couple one of the conductive lines 365-a-2 with one of the conductive lines 365-a-1 through the dielectric layer 340-a-2, and a via 345-a-3 may couple one of the conductive lines 365-a-3 with one of the conductive lines 365-a-2 through the dielectric layer 340-a-3. Although the vias 345-a of the semiconductor component 300-a each extend through a single dielectric layer 340-a, in some other examples, a via 345 may extend through multiple dielectric layers 340 (not shown), and each of such vias may be electrically coupled with or electrically isolated from conductive lines 365 of an interconnection layer 360 between such multiple dielectric layers 340.

In some examples, a thickness of a dielectric layer 340 (e.g., along the z-direction, between adjacent interconnection layers 360, between circuitry 320 and an interconnection layer 360) may be associated with a manufacturing characteristic (e.g., a deposition thickness, a deposition capability, a thickness tolerance), or a degree of isolation (e.g., a dielectric strength, an isolation tolerance, a threshold leakage resistance, a threshold capacitive coupling) between at least some circuitry of adjacent layers (e.g., between conductive lines 365, between conductive lines 365 and circuitry 320). For example, a thickness of at least a portion of a dielectric layer 340 may be configured for a threshold (e.g., minimum) resistance to charge leakage between conductors, or a threshold (e.g., maximum) capacitive coupling between conductors, among other characteristics. However, materials of dielectric layers 340 (e.g., dielectric materials) may have relatively a high thermal resistance (e.g., a relatively low thermal conductivity), which may limit an overall thermal conductivity through a semiconductor component 300 (e.g., along the z-direction) and be associated with relatively high internal temperatures of the semiconductor component. For example, a relatively high thermal resistance of dielectric layers 340 may impede dissipation of heat generated by operations of circuitry 320 or interconnection circuitry (e.g., conductive lines 365, vias 345), including such heat generated by circuit elements of the same semiconductor component 300, such heat generated by circuit elements of one or more adjacent (e.g., stacked, coupled) semiconductor components 300, or a combination thereof. Accordingly, a semiconductor component 300 may be configured with thermal vias in accordance with examples as disclosed herein, which may increase a degree of thermal conductivity through at least a portion of one or more dielectric layers 340.

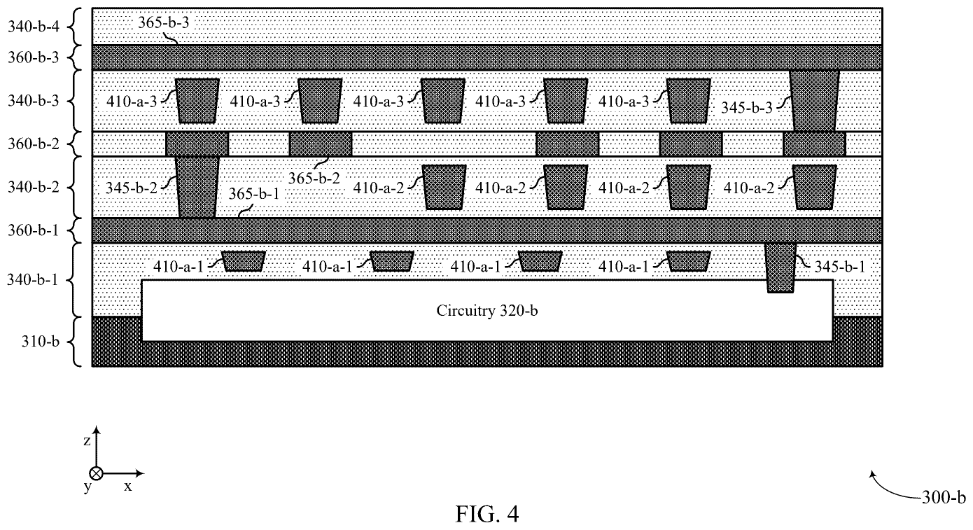

FIG. 4 shows an example of a semiconductor component 300-b that supports thermal vias in accordance with examples as disclosed herein. The semiconductor component 300-b includes a substrate 310-b, circuitry 320-b, dielectric layers 340-b (e.g., dielectric layers 340-b-1, 340-b-2, 340-b-3, and 340-b-4), and interconnection layers 360-b (e.g., interconnection layers 360-b-1, 360-b-2, 360-b-3). Aspects of the semiconductor component 300-b may be described with reference to an x-direction, a y-direction, and a z-direction of the illustrated coordinate system, with the illustration of FIG. 4 depicting aspects of the semiconductor component 300-b in an xz-plane (e.g., a cross-sectional plane) that may extend for some distance along the y-direction.

The semiconductor component 300-b illustrates an example for implementing thermal vias as conductor portions 410 (e.g., electrically isolated thermal vias, electrically floating thermal vias, enclosed thermal vias). Each of the conductor portions 410 may be enclosed by (e.g., surrounded by, in all directions) one or more dielectric materials, such as being enclosed within a given dielectric layer 340. For example, the semiconductor component 300-b includes conductor portions 410-a-1 enclosed within the dielectric layer 340-b-1, conductor portions 410-a-2 enclosed within the dielectric layer 340-b-2, and conductor portions 410-a-3 enclosed within the dielectric layer 340-b-3. The conductor portions 410 may not be electrically connected with other (e.g., operative, signal carrying) conductors, such as conductive lines 365 or conductors of circuitry 320. However, as a result of including conductor portions 410, a thermal conductivity through respective dielectric layers 340 may be higher along paths (e.g., paths along the z-direction, at locations in an xy-plane) through conductor portions 410 than along paths between conductor portions 410, which may provide a net increase in thermal conductivity through the semiconductor component 300-b (e.g., along the z-direction), or more-uniform temperature distribution in x-directions or y-directions, or both.

Conductor portions 410 may each include one or more conductive materials. In some examples, at least some of the conductor portions 410 may include a same material as vias 345, such as a same material as vias 345 that extend through a same dielectric layer 340 as the conductor portions 410. For example, conductor portions 410-a-1 may include one or more same conductive materials as vias 345-b-1, conductor portions 410-a-2 may include one or more same conductive materials as vias 345-b-2 (e.g., which may be the same as or different than vias 345-b-1), and so on. In some examples, forming at least some of the conductor portions 410 may implement one or more common operations as forming vias 345, such as one or more common material removal operations or one or more common material formation operations.

In some examples, at least some of the conductor portions 410 may have dimensions (e.g., in an xy-plane) that are the same as or similar to dimensions as vias 345 (e.g., of a same dielectric layer 340, of different dielectric layers 340). For example, conductor portions 410 may have a width dimension (e.g., along the x-direction, along the y-direction, or both) that is the same as vias 345, within 5 percent of vias 345, within 10 percent of vias 345, within 15% of vias 345, or within some other tolerance of vias 345. In some examples, conductor portions 410 may be smaller than vias 345 (e.g., of a same dielectric layer 340, of different dielectric layers). In some examples, at least some of the conductor portions 410 may have dimensions (e.g., in an xy-plane) that are narrower than conductive lines 365 (e.g., of one or more adjacent interconnection layers 360). For example, conductor portions 410-a-2 may have a width along the x-dimension that is smaller than the width dimension of conductive lines 365-b-2, a width along the y-dimension that is smaller than the width dimension of conductive lines 365-b-1, or both, and so on.

In some examples, at least some of the conductor portions 410 may be arranged in accordance with a pitch dimension over a substrate 310 (e.g., a center-to-center separation dimension, a dimension of repetition, from one conductor portion 410 to another, along the x-direction, along the y-direction). In some such examples, at least some of the conductor portions 410 may be arranged in accordance with a pitch dimension that is common with a pitch dimension of conductive lines 365, a pitch dimension of vias 345, or both. For example, conductor portions 410-a-3 may be arranged in accordance with a pitch dimension along the y-direction that is common with a pitch dimension of vias 345-b-3, with a pitch dimension along the y-direction that is common with a pitch dimension of conductive lines 365-b-3, or both, and so on. Additionally, or alternatively, conductor portions 410-a-3 may be arranged in accordance with a pitch dimension along the x-direction that is common with a pitch dimension of vias 345-b-3 or vias 345-b-2, with a pitch dimension along the x-direction that is common with a pitch dimension of conductive lines 365-b-2, or both, and so on. In some examples, conductor portions 410 may be arranged with a pitch dimension that is different than other features. For example, conductor portions 410)-a-1 may be arranged between the interconnection layer 360-b and the circuitry 320-b (e.g., within the dielectric layer 340-b-1) with a pitch dimension (e.g., along the x-direction, along the y-direction, or both) that is different than pitch dimensions for conductive lines 365, vias 345, or both, and so on.

In some examples, at least some of the conductor portions 410 may be aligned (e.g., along the z-direction) with other features of a semiconductor component 300. For example, when viewed along the z-direction, a cross section of at least some of the conductor portions 410-b-3 may be overlapping with at least one (e.g., a single one) of the conductive lines 365-b-3, at least one (e.g., a single one) of the conductive lines 365-b-2, or both, and so on. Additionally, or alternatively, when viewed along the z-direction, a cross section of at least some of the conductor portions 410-a-2 may be overlapping with at least one (e.g., a single one) of the vias 345-b-3, at least one (e.g., a single one) of the vias 345-b-2, or both, and so on.

Because conductor portions 410 are not electrically connected with other conductors of a semiconductor component 300 they may, in some examples, be located anywhere within one or more dielectric layers 340 of a semiconductor component 300. However, conductor portion 410 may be located in certain areas to support manufacturing, mechanical, or electrical characteristics, or any combination thereof. For example, locating conductor portions 410 with common pitch dimensions, width dimensions, or alignment as other features of a semiconductor component may support aspects of manufacturing uniformity, mechanical stability, tolerancing, or reliability, among other benefits. Further, although conductor portions 410 may not be electrically connected with other conductors, they may support some degree of capacitive coupling with or between neighboring conductors, which may affect electrical characteristics of operating a semiconductor component 300. Accordingly, although some conductor portions 410 may be arranged in accordance with a pitch dimension, some instances of conductor portions 410 may be omitted in locations where such a capacitive coupling may adversely affect operations of the semiconductor component 300, among other examples.

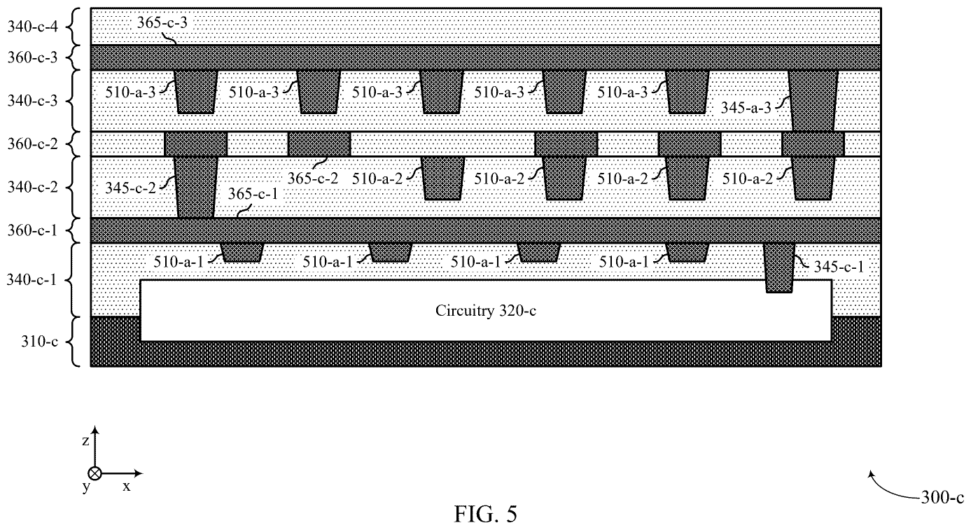

FIG. 5 shows an example of a semiconductor component 300-c that supports thermal vias in accordance with examples as disclosed herein. The semiconductor component 300-c includes a substrate 310-c, circuitry 320-c, dielectric layers 340-c (e.g., dielectric layers 340-c-1, 340-c-2, 340-c-3, and 340-c-4), and interconnection layers 360-c (e.g., interconnection layers 360-c-1, 360-c-2, 360-c-3). Aspects of the semiconductor component 300-c may be described with reference a x-direction, a y-direction, and a z-direction of the illustrated coordinate system, with the illustration of FIG. 5 depicting aspects of the semiconductor component 300-c in an xz-plane (e.g., a cross-sectional plane) that may extend for some distance along the y-direction.

The semiconductor component 300-c illustrates an example for implementing thermal vias as conductor portions 510 (e.g., electrically connected thermal vias, electrically contiguous thermal vias, materially contiguous thermal vias). Each of the conductor portions 510 may be partially enclosed by one or more dielectric materials of a given dielectric layer 340, but may be coincident with a surface of the given dielectric layer (e.g., an xy-boundary, along the z-direction) which, in some examples, may support a conductor portion 510 being in contact with another conductor (e.g., a conductive line 365, a conductor of circuitry 320). For example, the semiconductor component 300-c includes conductor portions 510-a-1 of (e.g., in, projecting into) the dielectric layer 340-c-1 that may be coincident with conductive lines 365-c-1, conductor portions 510-a-2 of (e.g., in, projecting into) the dielectric layer 340)-c-2 that may be coincident with conductive lines 365-c-2, and conductor portions 510-a-2 of (e.g., in, projecting into) the dielectric layer 340-c-2 that may be coincident with conductive lines 365-c-3. As a result of including conductor portions 510, a thermal conductivity through respective dielectric layers 340 may be higher along paths (e.g., paths along the z-direction, at locations in an xy-plane) through conductor portions 510 than along paths between conductor portions 510, which may provide a net increase in thermal conductivity through the semiconductor component 300-c (e.g., along the z-direction), or more-uniform temperature distribution in x-directions or y-directions, or both.

In some examples, conductor portions 510 may be operable (e.g., current-carrying, signal-carrying) portions of conductors, such as conductive lines 365 or conductors of circuitry 320) (not shown). For example, conductive lines 365-c may be described as having a first thickness (e.g., a relatively smaller thickness, along the z-direction) between conductor portions 510 (e.g., in an xy-plane, along the x-direction, along the y-direction), and having a second thickness (e.g., a relatively larger thickness) through conductor portions 510. Further, conductive lines 365 may be described as having a first separation distance (e.g., isolation distance, dielectric thickness) from a neighboring interconnection layer 360 (e.g., a relatively larger distance, along the z-direction) between conductor portions 510, and a second separation distance (e.g., isolation distance, dielectric thickness) from the neighboring interconnection layer 360 (e.g., a relatively smaller distance) between conductor portions 510. For example, first portions of conductive material of conductive lines 365-c-3 and conductive portions 510-a-3 may be separated from the interconnection layer 360-c-2 by a first thickness of (e.g., a relatively thinner portion of) the dielectric material of the dielectric layer 340-c-3, and second portions of conductive material of conductive lines 365-3 (e.g., between conductive portions 510-a-3 may be separated from the interconnection layer 360-c-2 by a second thickness of (e.g., a relatively thicker portion of) the dielectric material of the dielectric layer 340-c-3. Although conductor portions 510 are illustrated as projecting along a negative z-direction (e.g., downward) from a surface of interconnection layers 360 and dielectric layers 340 (e.g., from an interface therebetween), in some examples, conductor portions 510 of a semiconductor may additionally, or alternatively, project along a positive z-direction.

Conductor portions 510 may each include one or more conductive materials. In some examples, at least some of the conductor portions 510 may include a same material as vias 345, such as a same material as vias 345 that extend through a same dielectric layer 340 as the conductor portions 510. For example, conductor portions 510-a-1 may include one or more same conductive materials as vias 345-c-1, conductor portions 510-a-2 may include one or more same conductive materials as vias 345-c-2 (e.g., which may be the same as or different than vias 345-c-1), and so on. In some examples, at least some of the conductor portions 510 may include a same material as conductive lines 365, such as a same material as conductive lines 365 from which conductor portions 510 extend. For example, conductor portions 510-a-1 may include one or more same conductive materials as conductive lines 365-c-1, conductor portions 510-a-2 may include one or more same conductive materials as conductive lines 365-c-2 (e.g., which may be the same as or different than conductive lines 365-c-1), and so on.

In some examples, forming at least some of the conductor portions 510 may implement one or more common operations as forming conductive lines 365, such as one or more common material removal operations or one or more common material formation operations. For example, conductive materials of conductor portions 510-a-3 may be formed concurrently with (e.g., contiguously with, without deposition boundary between) one or more conductive materials of conductive lines 365-c-3, such as a conductor deposition operation configured to form the one or more conductive materials along two different depths (e.g., along the z-direction, through a common opening, in a dual damascene conductor formation operation), and so on. Additionally, or alternatively, in some examples, forming at least some of the conductor portions 510 may implement one or more common operations as forming vias 345, such as one or more common material removal operations or one or more common material formation operations. For example, conductive materials of conductor portions 510-a-2 may be formed concurrently with (e.g., contiguously with, without deposition boundary between) one or more conductive materials of vias 345-c-2, such as a conductor deposition operation configured to form the one or more conductive materials along three different depths (e.g., along the z-direction, through a common opening, in a triple damascene conductor formation operation for forming conductive lines 365-c-2, conductor portions 510-a-2, and vias 345-c-2), and so on.

In some examples, at least some of the conductor portions 510 may have dimensions (e.g., in an xy-plane) that are the same as or similar to dimensions as vias 345 (e.g., into a same dielectric layer 340, into different dielectric layers 340). For example, conductor portions 510 may have a width dimension (e.g., an opening dimension, a dimension at an interface between an interconnection layer 360 and a dielectric layer 340) along the x-direction, along the y-direction, or both) that is the same as vias 345, within 5 percent of vias 345, within 10 percent of vias 345, within 15% of vias 345, or within some other tolerance of vias 345. In some examples, conductor portions 510 may be smaller than vias 345 (e.g., into a same dielectric layer 340, into different dielectric layers). In some examples, at least some of the conductor portions 510 may have dimensions (e.g., in an xy-plane, at an interface between an interconnection layer 360 and a dielectric layer 340) that are narrower than conductive lines 365 (e.g., of one or more adjacent interconnection layers 360). For example, conductor portions 510-a-2 may have a width along the x-dimension that is smaller than the width dimension of conductive lines 365-c-2, a width along the y-dimension that is smaller than the width dimension of conductive lines 365-c-1, or both, and so on.

In some examples, at least some of the conductor portions 510 may be arranged in accordance with a pitch dimension over a substrate 310 (e.g., a center-to-center separation dimension, a dimension of repetition, from one conductor portion 510 to another, along the x-direction, along the y-direction). In some such examples, at least some of the conductor portions 510 may be arranged in accordance with a pitch dimension that is common with a pitch dimension of conductive lines 365, a pitch dimension of vias 345, or both. For example, conductor portions 510-a-3 may be arranged in accordance with a pitch dimension along the y-direction that is common with a pitch dimension of vias 345-a-3, with a pitch dimension along the y-direction that is common with a pitch dimension of conductive lines 365-c-3, or both, and so on. Additionally, or alternatively, conductor portions 510-a-3 may be arranged in accordance with a pitch dimension along the x-direction that is common with a pitch dimension of vias 345-a-3 or vias 345-a-2, with a pitch dimension along the x-direction that is common with a pitch dimension of conductive lines 365-c-2, or both, and so on. In some examples. conductor portions 510 may be arranged with a pitch dimension that is different than other features. For example, conductor portions 510-a-1 may be arranged between the interconnection layer 360-c and the circuitry 320-c (e.g., into the dielectric layer 340-c-1) with a pitch dimension (e.g., along the x-direction, along the y-direction, or both) that is different than pitch dimensions for conductive lines 365, vias 345, or both, and so on.

In some examples, at least some of the conductor portions 510 may be aligned (e.g., along the z-direction) with other features of a semiconductor component 300. For example, when viewed along the z-direction, a cross section of at least some of the conductor portions 510-a-3 may be overlapping with a single one of the conductive lines 365-c-3, at least one (e.g., a single one, more than one) of the conductive lines 365-c-2, or both, and so on. Additionally, or alternatively, when viewed along the z-direction, a cross section of at least some of the conductor portions 510-a-2 may be overlapping with a single one of the vias 345-c-3 or a single one of the vias 345-c-2, and so on.

Because conductor portions 510 may be electrically connected with other conductors of a semiconductor component 300 they may be located in areas in which such electrical connections do not adversely affect operations of the semiconductor component. Nonetheless, conductor portion 510 may still be located in certain areas to support manufacturing, mechanical, or electrical characteristics, or any combination thereof. For example, locating conductor portions 510 with common pitch dimensions, width dimensions, or alignment as other features of a semiconductor component may support aspects of manufacturing uniformity, mechanical stability, tolerancing, or reliability, among other benefits. Further, although conductor portions 510 may not be electrically connected with some conductors, they may support some degree of capacitive coupling with or between such conductors, which may affect electrical characteristics of operating a semiconductor component 300. Accordingly, although some conductor portions 510 may be arranged in accordance with a pitch dimension, some instances of conductor portions 510 may be omitted in locations where such a capacitive coupling may adversely affect operations of the semiconductor component 300, among other examples.

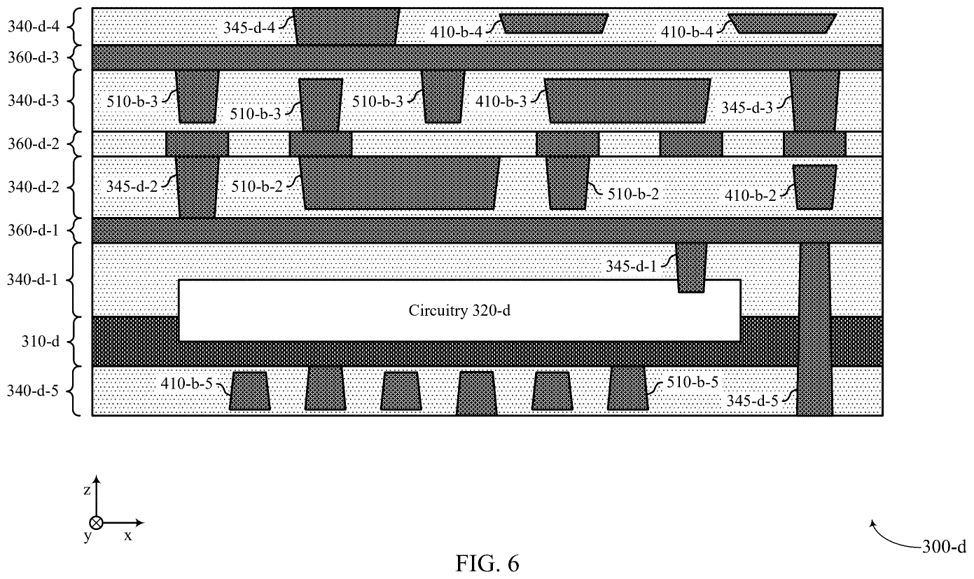

FIG. 6 shows an example of a semiconductor component 300-d that supports thermal vias in accordance with examples as disclosed herein. The semiconductor component 300-d includes a substrate 310-d, circuitry 320-d, dielectric layers 340-d (e.g., dielectric layers 340-d-1, 340-d-2, 340-d-3, 340-d-4, and 340-d-5), and interconnection layers 360-d (e.g., interconnection layers 360-d-1, 360-d-2, 360-d-3). Aspects of the semiconductor component 300-d may be described with reference a x-direction, a y-direction, and a z-direction of the illustrated coordinate system, with the illustration of FIG. 6 depicting aspects of the semiconductor component 300-d in an xz-plane (e.g., a cross-sectional plane) that may extend for some distance along the y-direction.

The semiconductor component 300-d illustrates an example for implementing thermal vias in various configurations as conductor portions 410 and conductor portions 510. For example, at least some of the dielectric layers 340 of the semiconductor component 300-d may include a combination of one or more conductor portions 410-b and one or more conductor portions 510-a. The semiconductor component 300-d also illustrates that at least some vias 345 may extend through multiple dielectric layers 340 (e.g., vias 345-d-5 extending through dielectric layers 340-d-1 and 340-d-5), or may extend to a surface of a semiconductor component 300 (e.g., as conductive contacts, vias 345-d-4 extending to a first surface, such as a front-side surface, vias 345-d-5 extending to a second surface, such a back-side surface), or may be through-silicon vias (TSVs) (e.g., vias 345-d-5 extending through the substrate 310-d). Although certain examples of conductor portions 410 and conductor portions 510, and combinations thereof, are illustrated in the example of semiconductor component 300-d, a semiconductor component 300 in accordance with the described techniques may implement any one or more of such conductor portions 410, conductor portions 510, or combinations thereof, among other implementations.

In some examples, conductor portions 410 of a semiconductor component 300 may have different dimensions (e.g., width dimensions, pitch dimensions), or conductor portions 510 of a semiconductor component 300 may have different dimensions (e.g., width dimensions, pitch dimensions), or both (e.g., within a dielectric layer 340, across multiple dielectric layers 340). For example, one or more conductor portions 410-b-3 of the dielectric layer 340-d-3 may have a different width along the x-direction than one or more conductor portions 410-b-2 of the dielectric layer 340-d-2. In various examples, conductor portions 410-b-3 may have different dimensions along the y-direction (e.g., width dimensions, pitch dimensions) or same dimensions as conductor portions 410-b-2. Further, one or more conductor portions 510-b-2 of the dielectric layer 340-d-2 may have different width dimensions (e.g., along the x-direction) than one or more other conductor portions 510-b-2 of the dielectric layer 340-d-2. In some examples, wider conductor portions 510 may be enabled by an absence of a conductive line 365 at a portion of an interface between a dielectric layer 340 and the corresponding interconnection layer 360. In some examples, a width (e.g., in an xy-plane) or pitch dimension may be the same between at least some conductor portions 410 and at least some conductor portions 510 (e.g., within a dielectric layer 340, across multiple dielectric layers 340).

The semiconductor component 300-d also illustrates an example of thermal vias on an outer-most dielectric layer 340 (e.g., of dielectric layer 340-d-4, at a surface of the semiconductor component 300-d, beyond an upper-most interconnection layer 360-d-3) in the form of conductor portions 410-b-4, 410-b-5, and 510-b-5. However, in various implementations, such surface-layer thermal vias may include conductor portions 410, conductor portions 510, or a combination thereof, and conductor portions 510 of an outer dielectric layer 340 may be implemented as extending from a surface of an interconnection layer 360, extending from an outer surface of the semiconductor component 300, or both.

The semiconductor component 300-d also illustrates an example back-side thermal vias, in the form of conductor portions 410-b-5 and conductor portions 510-b-5. A semiconductor component 300 may also include back-side interconnection layers 360 (not shown), and such a semiconductor component 300 may include thermal vias (e.g., conductor portions 410, conductor portions 510, or both) between a substrate 310 and a back-side interconnection layer 360, between back-side interconnection layers 360, or beyond a back-side interconnection layer 360 (e.g., along the negative z-direction).

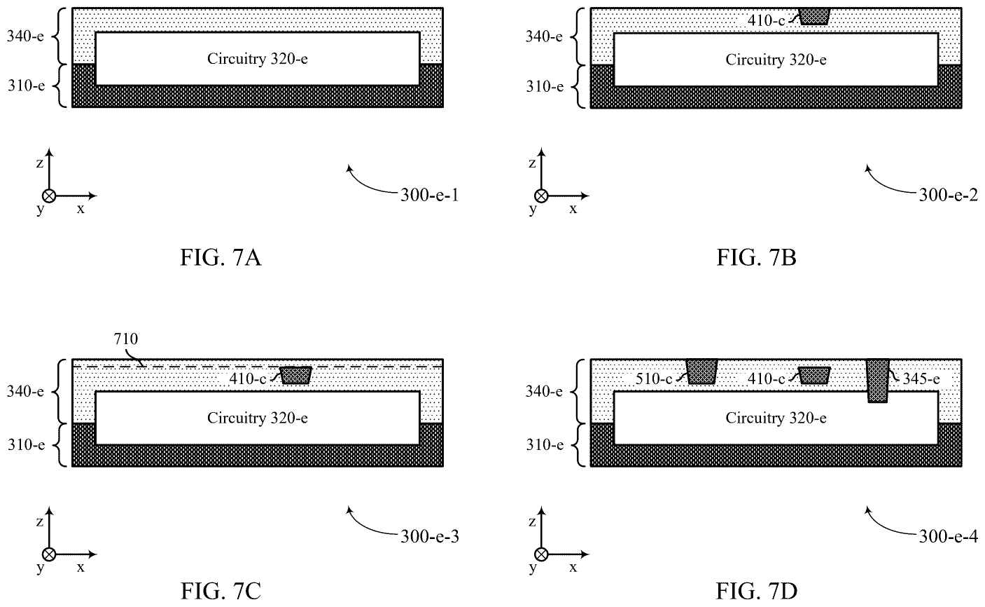

FIGS. 7A through 7D show examples of fabrication operations that support thermal vias in accordance with examples as disclosed herein. For example, FIGS. 7A through 7D may illustrate a sequence of operations for fabricating aspects of a semiconductor component 300-e (e.g., a wafer, a die, a chiplet), which may be a portion of a system 100 (e.g., a host system 105, a memory system 110, or a combination thereof), or a system 200 (e.g., a die 205, a die 240), or another implementation of a semiconductor component (e.g., a memory component, a processing component). Such techniques may include aspects of forming a conductor portion 410-c, a conductor portion 510-c, a via 345-e, or a combination thereof. Although single instances of such features are illustrated in the semiconductor component 300-e, such techniques may be performed to form any quantity of one or more conductor portions 410-c, one or more conductor portions 510-c, one or more vias 345, or a combination thereof.

Each of FIGS. 7A through 7D may illustrate aspects of the semiconductor component 300-e after different subsets of the fabrication operations for forming the semiconductor component 300 (e.g., illustrated as a semiconductor component 300-e-1 after a first set of one or more fabrication operations, as a semiconductor component 300-e-2 after a second set of one or more fabrication operations, and so on). Each view of FIGS. 7A through 7D may be described with reference to an x-direction, a y-direction, and a z-direction of the illustrated coordinate system. Aspects of the semiconductor component 300-e may be illustrated in accordance with a cut plane (e.g., along an xz-plane) to show embedded features of the semiconductor component 300-e.

Operations illustrated in and described with reference to FIGS. 7A through 7D may be performed by a manufacturing system, such as a semiconductor fabrication system configured to perform additive operations (e.g., deposition, epitaxy, bonding), subtractive operations (e.g., etching, trenching, planarizing, polishing), modifying operations (e.g., oxidizing, doping, reacting, converting), and supporting operations (e.g., masking, patterning, photolithography, aligning), among other operations that support the described techniques for formation of the features of the semiconductor component 300-e. In some examples, operations performed by such a manufacturing system may be supported by a process controller or its components as described herein (e.g., including instructions stored in a non-transitory computer-readable medium that are executable by a processing system to cause the manufacturing system to perform the operations).

Although aspects of the semiconductor component illustrate examples of relative dimensions and quantities of various features, aspects of the semiconductor component 300-e may be implemented with other relative dimensions or quantities of such features in accordance with examples as disclosed herein. Moreover, aspects of the semiconductor component 300-e may be repeated in various manners (e.g., along the x-direction, along the y-direction, along the z-direction) to support two-dimensional array of thermal vias, among other features. In the following description of the semiconductor component 300-e, some methods, techniques, processes, and operations may be performed in different orders, or at different times, or otherwise modified. Further, some operations for fabricating a semiconductor component 300-e may be omitted from the described fabrication operations, or other operations may be added to the described fabrication operations.

FIG. 7A shows the semiconductor component 300-e (e.g., as a semiconductor component 300-e-1) after a first set of one or more fabrication operations. For example, the first set of operations may include forming circuitry 320-e (e.g., FEOL circuitry), which may include circuit elements (e.g., transistors) formed at least in part from a doped portion of a substrate 310-e. The first set of operations may also include forming a dielectric material over the circuitry 320-e, which may form at least a portion of a dielectric layer 340-e.

FIG. 7B shows the semiconductor component 300-e (e.g., as a semiconductor component 300-e-2) after a second set of one or more fabrication operations. For example, the second set of operations may include forming a conductor portion 410-c. In some examples, forming the conductor portion 410-c may include forming a cavity through a portion of the dielectric layer 340-e (e.g., along the z-direction, from a surface in an xy-plane), and forming a conductive material in the cavity. In some examples, a depth of the cavity may be controlled based on a duration of an etching operation, or based on a differential material removal operation that stops at a material layer (e.g., an etch stop material, above the circuitry 320-e) of the dielectric layer 340-e. In some examples, a top surface of the conductor portion 410-c (e.g., along the z-direction, in an xy-plane) may be established based on a surfacing operation (e.g., a chemical-mechanical polishing (CMP) operation).

FIG. 7C shows the semiconductor component 300-e (e.g., as a semiconductor component 300-e-3) after a third set of one or more fabrication operations. For example, the third set of operations may include forming a dielectric material over the conductor portion 410-c (e.g., over a surface 710), which may be part of enclosing the conductor portion 410-c in one or more dielectric materials. The dielectric material formed in the third set of operations may be part of forming the dielectric layer 340-e, and may be the same as or different than a dielectric material formed in the first set of operations.

FIG. 7D shows the semiconductor component 300-e (e.g., as a semiconductor component 300-e-2) after a fourth set of one or more fabrication operations. For example, the fourth set of operations may include forming a conductor portion 510-c. In some examples. forming the conductor portion 410-c may include forming a cavity through a portion of the dielectric layer 340-e (e.g., along the z-direction, from a surface in an xy-plane), and forming a conductive material in the cavity. In some examples, a depth of the cavity may be controlled based on a duration of an etching operation, or based on a differential material removal operation that stops at a material layer of the dielectric layer 340-e, and may be the same as or different than a depth of a cavity for forming the conductor portion 410-c. Additionally, or alternatively, the fourth set of operations may include forming a via 345-e. In some examples, forming the via 345-e may include forming a cavity through a portion of the dielectric layer 340-e (e.g., along the z-direction, from a surface in an xy-plane), and forming a conductive material in the cavity. In some examples, a depth of the cavity may be controlled based on a differential material removal operation that stops at a conductor of the circuitry 320-e (e.g., to form at least a portion of a conductive path coupled with the circuitry 320-e. In some examples, a top surface of a conductor portion 510-c, a via 345-e, or both may be established based on a surfacing operation (e.g., a chemical-mechanical polishing (CMP) operation).

After the fourth set of operations, in some examples, one or more conductive paths of an interconnection layer 360 may be formed (e.g., by forming portions of a conductive material over the dielectric layer 340-e. In some examples, aspects of the second, third, and fourth sets of operations may be repeated to form one or more additional dielectric layers or one or more interconnection layers, which may include additional instances of conductor portions 410, conductor portions 510, or vias 345, or any combination thereof. Further, although aspects of forming conductor portions 410-c, conductor portions 510-c, and vias 345-e are illustrated and described with reference to a front side of the substrate 310-a (e.g., a same side as circuitry 320-e is formed), one or more aspects of forming conductor portions 410, conductor portions 510, and vias 345 may additionally, or alternatively, be performed on a back side of a substrate 310.

As a result of including conductor portions 410, conductor portions 510, or both in accordance with these and other techniques, thermal conductivity through respective dielectric layers 340 may be higher along paths (e.g., paths along the z-direction, at locations in an xy-plane) through conductor portions 410 and/or 510 than along paths between conductor portions 410 and/or 510, which may provide a net increase in thermal conductivity through the semiconductor component 300 (e.g., along the z-direction), or more-uniform temperature distribution in x-directions or y-directions, or both. Configuring a semiconductor component 300 with such thermal vias may support reduced internal temperatures while operating the semiconductor component 300, or may support an increased device density (e.g., transistor density, heat density) of the semiconductor component 300, or both, which may support higher performance semiconductor components 300 or assemblies (e.g., stacks) thereof.

The described techniques for thermal vias may be implemented in various types of semiconductor components. For example, conductor portions 410, conductor portions 510, or a combination thereof may be implemented in a memory system 110 (e.g., memory devices 145, memory dies), such as DRAM devices (e.g., 2D DRAM devices, 3D DRAM devices), NAND devices (e.g., 2D NAND devices, 3D NAND devices), and other memory systems or components thereof, which each may be formed using one or more semiconductor components 300. Additionally, or alternatively, conductor portions 410, conductor portions 510, or a combination thereof may be implemented in processing devices, such as in a host system 105 (e.g., a processor 125, a host system controller 120, a host processor 210, a controller 215), and other processing systems or components thereof. In some examples, such techniques may be implemented in stacked semiconductor devices (e.g., semiconductor devices including a stacked set of multiple semiconductor components 300, such as a system 200 including a die 205 and one or more die 240, or a memory device 145 that includes other architectures with memory cells on one semiconductor component 300 and logic for operating the memory cells on another semiconductor component, among other implementations), such that conductor portions 410, conductor portions 510, or both may be located in one or more semiconductor components 300 between semiconductor substrates (e.g., between two substrates 310 of semiconductor components 300 that are bonded together), or outside semiconductor substrates (e.g., along a stacking direction), or both. In these and other examples, conductor portions 410, conductor portions 510, or a combination thereof may be implemented in a given semiconductor component 300 as front-side thermal vias (e.g., on a same side of a substrate 310 that is doped to form transistor circuitry, on a side of a substrate upon which FEOL operations are performed), or as back-side thermal vias (e.g., on a side opposite from which a substrate 310 is doped to form transistor circuitry, or both.

An apparatus is described. The following provides an overview of aspects of the apparatus as described herein:

Aspect 1: A semiconductor component (e.g., a system 100 or portion thereof, a host system 105 or portion thereof, a processor 125, a memory system 110 or portion thereof, a memory device 145, a system 200 or portion thereof, a die 205, a die 240), including: a semiconductor substrate (e.g., a substrate 310): circuitry formed at least in part from a doped portion of the semiconductor substrate (e.g., circuitry 320): a first interconnection layer (e.g., an interconnection layer 360) over the semiconductor substrate, the first interconnection layer including a plurality of first conductive lines (e.g., conductive lines 365) extending over the semiconductor substrate: a second interconnection layer (e.g., an interconnection layer 360) between the first interconnection layer and the semiconductor substrate, the second interconnection layer including a plurality of second conductive lines extending over the semiconductor substrate: a dielectric layer (e.g., a dielectric layer 340) between the first interconnection layer and the second interconnection layer: and a plurality of conductor portions (e.g., conductor portions 410) enclosed within the dielectric layer.

Aspect 2: The semiconductor component of aspect 1, further including a plurality of conductive vias (e.g., vias 345) coupling the plurality of first conductive lines with the plurality of second conductive lines through the dielectric layer.

Aspect 3: The semiconductor component of aspect 2, where the plurality of

conductive vias are formed at least in part with a conductive material, and the plurality of conductor portions are formed at least in part with the conductive material.

Aspect 4: The semiconductor component of any of aspects 2 through 3, where the plurality of conductive vias are associated with a first width dimension (e.g., in an xy-plane), and the plurality of conductor portions are associated with a second width dimension that is within ten percent of the first width dimension.

Aspect 5: The semiconductor component of any of aspects 2 through 4, where at least a portion of the plurality of conductive vias are arranged in accordance with a pitch dimension (e.g., in an xy-plane) over the semiconductor substrate, and at least a portion of the plurality of conductor portions are arranged in accordance with the pitch dimension over the semiconductor substrate.

Aspect 6: The semiconductor component of any of aspects 2 through 5, further including a plurality of second conductive vias (e.g., vias 345) coupling the plurality of second conductive lines with the circuitry formed at least in part from the doped portion of the semiconductor substrate.

Aspect 7: The semiconductor component of any of aspects 1 through 6, where at least one of the plurality of conductor portions has a width (e.g., in an xy-plane) that is smaller than a width of the plurality of first conductive lines, smaller than a width of the plurality of second conductive lines, or both.

Aspect 8: The semiconductor component of any of aspects 1 through 7, where at least a portion of the plurality of first conductive lines are arranged in accordance with a pitch dimension (e.g., in an xy-plane) over the semiconductor substrate, and at least a portion of the plurality of conductor portions are arranged in accordance with the pitch dimension over the semiconductor substrate.

Aspect 9: The semiconductor component of any of aspects 1 through 8, where, along a direction between the first interconnection layer and the second interconnection layer (e.g., along a thickness direction, along a z-direction), a cross section of one or more of the plurality of conductor portions is overlapping with a cross section of at least one of the plurality of first conductive lines, overlapping with a cross section of at least one of the plurality of second conductive lines, or both.

Aspect 10: The semiconductor component of any of aspects 1 through 9, where, along a direction between the first interconnection layer and the second interconnection layer (e.g., along a thickness direction, along a z-direction), a cross section of one or more of the plurality of conductor portions is overlapping with a cross section of a single one of the plurality of first conductive lines, overlapping with a cross section of a single one of the plurality of second conductive lines, or both.

Aspect 11: The semiconductor component of any of aspects 1 through 10, where the first interconnection layer and the second interconnection layer are arranged on a same side of the semiconductor substrate that is doped to form the circuitry (e.g., a front side).

Aspect 12: The semiconductor component of any of aspects 1 through 11, where the circuitry includes transistor circuitry of one or more processors.

Aspect 13: The semiconductor component of any of aspects 1 through 12, where a thermal conductivity through the dielectric layer is higher at a first location through a conductor portion of the plurality of conductor portions than at a second location between conductor portions of the plurality of conductor portions.

An apparatus is described. The following provides an overview of aspects of the apparatus as described herein:

Aspect 14: A semiconductor component (e.g., a system 100 or portion thereof, a host system 105 or portion thereof, a processor 125, a memory system 110 or portion thereof, a memory device 145, a system 200 or portion thereof, a die 205, a die 240), including: a memory array (e.g., a memory array 155, a memory array 250): transistor circuitry configured for accessing the memory array, the transistor circuitry formed at least in part from a doped portion of a semiconductor substrate (e.g., a substrate 310) of the semiconductor component: an interconnection layer (e.g., an interconnection layer 360) over the semiconductor substrate, the interconnection layer including a plurality of conductive lines (e.g., conductive lines 365) extending over the semiconductor substrate: a dielectric layer (e.g., a dielectric layer 340) over the semiconductor substrate and adjacent to the interconnection layer along a direction (e.g., a thickness direction, a z-direction) from the semiconductor substrate: and a plurality of conductor portions (e.g., conductor portions 410) enclosed within the dielectric layer.

An apparatus is described. The following provides an overview of aspects of the apparatus as described herein:

Aspect 15: A semiconductor component (e.g., a system 100 or portion thereof, a host system 105 or portion thereof, a processor 125, a memory system 110 or portion thereof, a memory device 145, a system 200 or portion thereof, a die 205, a die 240), including: a semiconductor substrate (e.g., a substrate 310): circuitry formed at least in part from a doped portion of the semiconductor substrate (e.g., circuitry 320); and an interconnection layer (e.g., an interconnection layer 360) over the semiconductor substrate, the interconnection layer including a plurality of conductive lines (e.g., conductive lines 365) extending over the semiconductor substrate, where one or more of the plurality of conductive lines includes: one or more first portions (e.g., between conductor portions 510) having a first thickness along a direction (e.g., a thickness direction, a z-direction) from the semiconductor substrate: and one or more second portions (e.g., through conductor portions 510) having a second thickness along the direction from the semiconductor substrate that is greater than the first thickness.

Aspect 16: The semiconductor component of aspect 15, where the one or more first portions and the one or more second portions are formed contiguously of a conductive material.

Aspect 17: The semiconductor component of any of aspects 15 through 16, further including a second interconnection layer (e.g., an interconnection layer 360) between the interconnection layer and the semiconductor substrate, the second interconnection layer including a plurality of second conductive lines (e.g., conductive lines 365) extending over the semiconductor substrate, where the one or more first portions are separated from the second interconnection layer by first dielectric portions (e.g., portions of the dielectric layer 340 aligned between conductor portions 510, portions of one or more dielectric materials) having a first thickness (e.g., along a z-direction), and the one or more second portions are separated from the second interconnection layer by second dielectric portions (e.g., portions of the dielectric layer 340 aligned along conductor portions 510), having a second thickness that is less than the first thickness.

Aspect 18: The semiconductor component of aspect 17, further including: a plurality of conductive vias (e.g., vias 345) coupling the plurality of conductive lines with the plurality of second conductive lines.

Aspect 19: The semiconductor component of aspect 18, where the one or more

first portions, the one or more second portions, and the plurality of conductive vias are formed contiguously of a conductive material (e.g., in a triple damascene process).

Aspect 20: The semiconductor component of any of aspects 18 through 19, where the plurality of conductive vias are associated with a first width dimension (e.g., in an xy-plane), and the one or more second portions are associated with a second width dimension that is within ten percent of the first width dimension.

Aspect 21: The semiconductor component of any of aspects 18 through 20, where at least a portion of the plurality of conductive vias are arranged in accordance with a pitch dimension (e.g., in an xy-plane) over the semiconductor substrate and at least one of the plurality of conductive lines includes two or more second portions that are arranged along the conductive line in accordance with the pitch dimension over the semiconductor substrate.

Aspect 22: The semiconductor component of any of aspects 17 through 21, further including a plurality of second conductive vias (e.g., vias 345) coupling the plurality of second conductive lines with the circuitry formed at least in part from the doped portion of the semiconductor substrate.

Aspect 23: The semiconductor component of any of aspects 15 through 22, where, for at least one of the plurality of conductive lines, at least one of the one or more second portions has a width (e.g., in an xy-plane) that is smaller than a width of the conductive line.

Aspect 24: The semiconductor component of any of aspects 15 through 23, where at least a portion of the plurality of conductive lines are arranged in accordance with a pitch dimension (e.g., in an xy-plane) over the semiconductor substrate, and at least one of the plurality of conductive lines includes two or more second portions that are arranged along the conductive line in accordance with the pitch dimension over the semiconductor substrate.

Aspect 25: The semiconductor component of any of aspects 15 through 24, where the interconnection layer is arranged on a same side of the semiconductor substrate that is doped to form the circuitry (e.g., a front side).

Aspect 26: The semiconductor component of any of aspects 15 through 25, where the circuitry includes transistor circuitry of one or more processors.

An apparatus is described. The following provides an overview of aspects of the apparatus as described herein:

Aspect 27: A semiconductor component (e.g., a system 100 or portion thereof, a host system 105 or portion thereof, a processor 125, a memory system 110 or portion thereof, a memory device 145, a system 200 or portion thereof, a die 205, a die 240), including: a memory array (e.g., a memory array 155, a memory array 250): transistor circuitry configured for accessing the memory array, the circuitry formed at least in part from a doped portion of a semiconductor substrate of the semiconductor component (e.g., circuitry 320); and an interconnection layer (e.g., an interconnection layer 360) over the semiconductor substrate, the interconnection layer including a plurality of conductive lines (e.g., conductive lines 365) extending over the semiconductor substrate, where one or more of the plurality of conductive lines includes: one or more first portions (e.g., portions between conductor portions 510) having a first thickness along a direction (e.g., a thickness direction, a z-direction) from the semiconductor substrate: and one or more second portions (e.g., through conductor portions 510) having a second thickness along the direction from the semiconductor substrate, the second thickness being greater than the first thickness.

An apparatus is described. The following provides an overview of aspects of the apparatus as described herein:

Aspect 28: A semiconductor system (e.g., a system 100 or portion thereof, a host system 105 or portion thereof, a processor 125, a memory system 110 or portion thereof, a memory device 145, a system 200 or portion thereof, a die 205, a die 240), including: a plurality of semiconductor components (e.g., semiconductor components 300) bonded in a stacked arrangement, where at least one of the plurality of semiconductor components includes: a semiconductor substrate (e.g., a substrate 310): circuitry formed at least in part from a doped portion of a semiconductor substrate (e.g., circuitry 320): a first interconnection layer (e.g., an interconnection layer 360) over the semiconductor substrate, the first interconnection layer including a plurality of first conductive lines (e.g., conductive lines 365) extending over the semiconductor substrate: a second interconnection layer (e.g., an interconnection layer 360) between the first interconnection layer and the semiconductor substrate, the second interconnection layer including a plurality of second conductive lines (e.g., conductive lines 365) extending over the semiconductor substrate: a dielectric layer (e.g., a dielectric layer 340) between the first interconnection layer and the second interconnection layer: and a plurality of conductor portions (e.g., conductor portions 410) enclosed within the dielectric layer.

An apparatus is described. The following provides an overview of aspects of the apparatus as described herein:

Aspect 29: A semiconductor system (e.g., a system 100 or portion thereof, a host system 105 or portion thereof, a processor 125, a memory system 110 or portion thereof, a memory device 145, a system 200 or portion thereof, a die 205, a die 240), including: a plurality of semiconductor components (e.g., semiconductor components 300) bonded in a stacked arrangement, where at least one of the plurality of semiconductor components includes: a semiconductor substrate (e.g., a substrate 310): circuitry formed at least in part from a doped portion of the semiconductor substrate (e.g., circuitry 320): and an interconnection layer (e.g., an interconnection layer 360) over the semiconductor substrate, the interconnection layer including a plurality of conductive lines (e.g., conductive lines 365) extending over the semiconductor substrate, where one or more of the plurality of conductive lines includes: one or more first portions (e.g., between conductor portions 510) having a first thickness along a direction (e.g., a thickness direction, a z-direction) from the semiconductor substrate: and one or more second portions (e.g., through conductor portions 510) having a second thickness along the direction from the semiconductor substrate, the second thickness being greater than the first thickness.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal: however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A semiconductor component, comprising:
a semiconductor substrate;
circuitry formed at least in part from a doped portion of the semiconductor substrate;
a first interconnection layer over the semiconductor substrate, the first interconnection layer comprising a plurality of first conductive lines extending over the semiconductor substrate;
a second interconnection layer between the first interconnection layer and the semiconductor substrate, the second interconnection layer comprising a plurality of second conductive lines extending over the semiconductor substrate;
a dielectric layer between the first interconnection layer and the second interconnection layer; and
a plurality of conductor portions enclosed within the dielectric layer.

2. The semiconductor component of claim 1, further comprising:
a plurality of conductive vias coupling the plurality of first conductive lines with the plurality of second conductive lines through the dielectric layer.

3. The semiconductor component of claim 2, wherein:
the plurality of conductive vias are formed at least in part with a conductive material; and
the plurality of conductor portions are formed at least in part with the conductive material.

4. The semiconductor component of claim 2, wherein:
the plurality of conductive vias are associated with a first width dimension; and
the plurality of conductor portions are associated with a second width dimension that is within ten percent of the first width dimension.

5. The semiconductor component of claim 2, wherein:
at least a portion of the plurality of conductive vias are arranged in accordance with a pitch dimension over the semiconductor substrate; and
at least a portion of the plurality of conductor portions are arranged in accordance with the pitch dimension over the semiconductor substrate.

6. The semiconductor component of claim 2, further comprising:
a plurality of second conductive vias coupling the plurality of second conductive lines with the circuitry formed at least in part from the doped portion of the semiconductor substrate.

7. The semiconductor component of claim 1, wherein at least one of the plurality of conductor portions has a width that is smaller than a width of the plurality of first conductive lines, smaller than a width of the plurality of second conductive lines, or both.

8. The semiconductor component of claim 1, wherein:
at least a portion of the plurality of first conductive lines are arranged in accordance with a pitch dimension over the semiconductor substrate; and
at least a portion of the plurality of conductor portions are arranged in accordance with the pitch dimension over the semiconductor substrate.

9. The semiconductor component of claim 1, wherein along a direction between the first interconnection layer and the second interconnection layer, a cross section of one or more of the plurality of conductor portions is overlapping with a cross section of at least one of the plurality of first conductive lines, overlapping with a cross section of at least one of the plurality of second conductive lines, or both.

10. The semiconductor component of claim 1, wherein along a direction between the first interconnection layer and the second interconnection layer, a cross section of one or more of the plurality of conductor portions is overlapping with a cross section of a single one of the plurality of first conductive lines, overlapping with a cross section of a single one of the plurality of second conductive lines, or both.

11. The semiconductor component of claim 1, wherein the first interconnection layer and the second interconnection layer are arranged on a same side of the semiconductor substrate that is doped to form the circuitry.

12. The semiconductor component of claim 1, wherein the circuitry comprises transistor circuitry of one or more processors.

13. The semiconductor component of claim 1, wherein a thermal conductivity through the dielectric layer is higher at a first location through a conductor portion of the plurality of conductor portions than at a second location between conductor portions of the plurality of conductor portions.

14. A semiconductor component, comprising:
a memory array;
transistor circuitry configured for accessing the memory array, the transistor circuitry formed at least in part from a doped portion of a semiconductor substrate of the semiconductor component;
an interconnection layer over the semiconductor substrate, the interconnection layer comprising a plurality of conductive lines extending over the semiconductor substrate;
a dielectric layer over the semiconductor substrate and adjacent to the interconnection layer along a direction from the semiconductor substrate; and
a plurality of conductor portions enclosed within the dielectric layer.

15. A semiconductor component, comprising:
a semiconductor substrate;
circuitry formed at least in part from a doped portion of the semiconductor substrate; and
an interconnection layer over the semiconductor substrate, the interconnection layer comprising a plurality of conductive lines extending over the semiconductor substrate, wherein one or more of the plurality of conductive lines comprises:
one or more first portions having a first thickness along a direction from the semiconductor substrate; and
one or more second portions having a second thickness along the direction from the semiconductor substrate that is greater than the first thickness.

16. The semiconductor component of claim 15, wherein the one or more first portions and the one or more second portions are formed contiguously of a conductive material.

17. The semiconductor component of claim 15, further comprising:
a second interconnection layer between the interconnection layer and the semiconductor substrate, the second interconnection layer comprising a plurality of second conductive lines extending over the semiconductor substrate, wherein:
the one or more first portions are separated from the second interconnection layer by first dielectric portions having a first thickness; and
the one or more second portions are separated from the second interconnection layer by second dielectric portions having a second thickness that is less than the first thickness.

18. The semiconductor component of claim 17, further comprising:
a plurality of conductive vias coupling the plurality of conductive lines with the plurality of second conductive lines.

19. The semiconductor component of claim 18, wherein the one or more first portions, the one or more second portions, and the plurality of conductive vias are formed contiguously of a conductive material.

20. The semiconductor component of claim 18, wherein:
the plurality of conductive vias are associated with a first width dimension; and
the one or more second portions are associated with a second width dimension that is within ten percent of the first width dimension.

21. The semiconductor component of claim 18, wherein:
at least a portion of the plurality of conductive vias are arranged in accordance with a pitch dimension over the semiconductor substrate; and
at least one of the plurality of conductive lines comprises two or more second portions that are arranged along the conductive line in accordance with the pitch dimension over the semiconductor substrate.

22. The semiconductor component of claim 17, further comprising:
a plurality of second conductive vias coupling the plurality of second conductive lines with the circuitry formed at least in part from the doped portion of the semiconductor substrate.

23. The semiconductor component of claim 15, wherein for at least one of the plurality of conductive lines, at least one of the one or more second portions has a width that is smaller than a width of the conductive line.

24. The semiconductor component of claim 15, wherein:
at least a portion of the plurality of conductive lines are arranged in accordance with a pitch dimension over the semiconductor substrate; and
at least one of the plurality of conductive lines comprises two or more second portions that are arranged along the conductive line in accordance with the pitch dimension over the semiconductor substrate.

25. The semiconductor component of claim 15, wherein the interconnection layer is arranged on a same side of the semiconductor substrate that is doped to form the circuitry.

26. The semiconductor component of claim 15, wherein the circuitry comprises transistor circuitry of one or more processors.

27. A semiconductor component, comprising:
a memory array;
transistor circuitry configured for accessing the memory array, the transistor circuitry formed at least in part from a doped portion of a semiconductor substrate of the semiconductor component; and
an interconnection layer over the semiconductor substrate, the interconnection layer comprising a plurality of conductive lines extending over the semiconductor substrate, wherein one or more of the plurality of conductive lines comprises:
one or more first portions having a first thickness along a direction from the semiconductor substrate; and
one or more second portions having a second thickness along the direction from the semiconductor substrate, the second thickness being greater than the first thickness.

28. A semiconductor system, comprising:
a plurality of semiconductor components bonded in a stacked arrangement, wherein at least one of the plurality of semiconductor components comprises:
a semiconductor substrate;
circuitry formed at least in part from a doped portion of the semiconductor substrate;
a first interconnection layer over the semiconductor substrate, the first interconnection layer comprising a plurality of first conductive lines extending over the semiconductor substrate;
a second interconnection layer between the first interconnection layer and the semiconductor substrate, the second interconnection layer comprising a plurality of second conductive lines extending over the semiconductor substrate;
a dielectric layer between the first interconnection layer and the second interconnection layer; and
a plurality of conductor portions enclosed within the dielectric layer.

29. A semiconductor system, comprising:
a plurality of semiconductor components bonded in a stacked arrangement, wherein at least one of the plurality of semiconductor components comprises:
a semiconductor substrate;
circuitry formed at least in part from a doped portion of the semiconductor substrate; and
an interconnection layer over the semiconductor substrate, the interconnection layer comprising a plurality of conductive lines extending over the semiconductor substrate, wherein one or more of the plurality of conductive lines comprises:
one or more first portions having a first thickness along a direction from the semiconductor substrate; and
one or more second portions having a second thickness along the direction from the semiconductor substrate, the second thickness being greater than the first thickness.
